(19) United States
(12) Patent Application Publication
(10) Pub. No.: US 2025/0273613 A1
(43) Pub. Date: Aug. 28, 2025

(54) METHODS AND APPARATUS TO IMPROVE RELIABILITY OF MULTI-LAYER VIAS

(71) Applicant: Intel Corporation, Santa Clara, CA (US)

(72) Inventors: Mohammad Enamul Kabir, Portland, OR (US); Adel A. Elsherbini, Chandler, AZ (US); Shawna Marie Liff, Scottsdale, AZ (US); Saurabh Chauhan, Beaverton, OR (US); Golsa Naderi, Portland, OR (US)

(73) Assignee: Intel Corporation, Santa Clara, CA (US)

(21) Appl. No.: 19/208,144

(22) Filed: May 14, 2025

(51) Int. Cl. H01L 23/00; H01L 23/538; H01L 25/065

(52) U.S. Cl. CPC H01L 24/20; H01L 23/5385; H01L 24/24; H01L 25/0657; H01L 24/16; H01L 24/73; H01L 2224/16225; H01L 2224/2101; H01L 2224/24146; H01L 2225/06517; H01L 2225/06541; H01L 2924/381

(57) ABSTRACT

Systems, apparatus, articles of manufacture, and methods to improve reliability of multi-layer vias are disclosed. An example apparatus includes: a first dielectric layer; a second dielectric layer; a metal layer between the first and second dielectric layers; a multi-layer via that extends through the first and second dielectric layers and through the metal layer; and a ring in the metal layer. The ring substantially encircles the multi-layer via.

### BACKGROUND

Semiconductor devices (e.g., integrated circuits (IC), semiconductor dies, etc.) include active components (e.g., transistors) constructed on a semiconductor substrate (e.g., a silicon wafer). In connection with the fabrication of these active components, alternating layers of metal and dielectric material are added to provide electrical interconnects that electrically couple the components of the overall integrated circuit. More particularly, the electrical interconnects are defined by traces and/or pads in the different metal layers that are electrically coupled between adjacent metal layers by conductive vias extending through the intervening dielectric layers.

### BRIEF DESCRIPTION OF THE DRAWINGS

FIG. 1 illustrates an example integrated circuit (IC) package constructed in accordance with teachings disclosed herein.

FIG. 2 is a cross-sectional view of an example semiconductor die constructed in accordance with teaching disclosed herein.

FIG. 3 is a cross-sectional side view of the example die of FIG. 2 taken along the line 3-3 of FIG. 2.

FIG. 4 is a cross-sectional top view of the example die of FIG. 2 taken along the line 4-4 of FIG. 2.

FIG. 5 is a top view of another example semiconductor die before the formation of an array of multi-layer vias.

FIG. 6 is top view of the example semiconductor die of FIG. 5 after the formation of the array of multi-layer vias.

FIG. 7 is a cross-sectional view of another example semiconductor die constructed in accordance with teaching disclosed herein.

FIG. 8 is a cross-sectional top view of the example die of FIG. 7 taken along the line 8-8 of FIG. 7.

FIG. 9 illustrates another example semiconductor die constructed in accordance with teaching disclosed herein.

FIG. 10 is a cross-sectional top view of the example die of FIG. 10 taken along the line 10-10 of FIG. 9.

FIG. 11 is a cross-sectional top view of the example die of FIG. 10 taken along the line 11-11 of FIG. 9.

FIG. 12 is a cross-sectional top view of the example die of FIG. 10 taken along the line 12-12 of FIG. 9.

FIG. 13 is a top view of another example semiconductor die constructed in accordance with teachings disclosed herein.

FIG. 14 is a cross-sectional side view of a portion of the example semiconductor die of FIG. 13.

FIGS. 15-28 illustrate different stages in an example fabrication process to manufacture any one of the example semiconductor dies of FIG. 1-14.

FIG. 29 is a flowchart representative of an example method of manufacturing any one of the example semiconductor dies of FIG. 1-28.

FIG. 30 is a top view of a wafer including dies that may be included in an IC package constructed in accordance with teachings disclosed herein.

FIG. 31 is a cross-sectional side view of an IC device that may be included in an IC package constructed in accordance with teachings disclosed herein.

FIG. 32 is a cross-sectional side view of an IC package that may include one or more example lateral etch casings surrounding one or more example multi-layer vias disclosed herein.

FIG. 33 is a cross-sectional side view of an IC device assembly that may include an IC package constructed in accordance with teachings disclosed herein.

FIG. 34 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

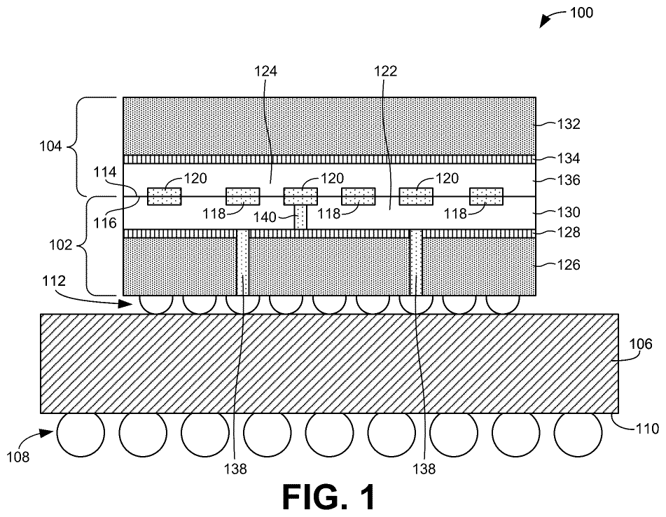

FIG. 1 illustrates an example integrated circuit (IC) package 100 constructed in accordance with teachings disclosed herein. In this example, the IC package 100 includes two semiconductor dies 102, 104 (e.g., silicon dies), sometimes also referred to as chips or chiplets, that are mounted to a package substrate 106. In the illustrated example, the package substrate 106 includes an array of first contacts 108 (e.g., first interconnects) on a package mounting surface 110 (e.g., a bottom surface, an external surface) of the package 100. In the illustrated example, the first contacts 108 are represented as balls. However, in some examples, the IC package 100 may include pads, lands, pins, and/or any other type(s) of contact, in addition to or instead of the balls shown to enable the electrical coupling of the IC package 100 to a printed circuit board (PCB).

As shown in the illustrated example, the first semiconductor die 102 is directly mounted and electrically coupled to the package substrate 106 by way of an array of second contacts 112 (e.g., second interconnects). In the illustrated example, the second contacts 112 are shown as bumps. In some examples, the second contacts 112 can include solder joints, micro bumps, combinations of metallic (e.g., copper) pillars and solder, etc. In other examples, the second contacts 112 may include directly bonded or “hybrid bonded” metallic interconnects. In other examples, the second contacts 112 may be any other type of electrical connection in addition to or instead of the bumps shown (e.g., balls, pins, pads, pillars, wire bonding, etc.). The electrical connections between the first die 102 and the package substrate 106 (e.g., the second contacts 112) are sometimes referred to as first level interconnects. By contrast, the electrical connections between the IC package 100 and an external circuit board (e.g., the first contacts 108) are sometimes referred to as second level interconnects.

In the example of FIG. 1, the second die 104 is stacked on top of the first die 102. More particularly, in this example, the second die 104 is mechanically and electrically coupled to the first die 102 by way of hybrid bonding. As used herein, hybrid bonding refers to a process of joining two substrates together by bringing mating surfaces of the two substrates into direct contact (without an adhesive) to allow direct chemical bonding (e.g., fusion bonding) of the materials exposed along the mating surfaces. Specifically, hybrid bonding includes at least two different materials exposed along one of the mating surface that chemically bond with corresponding portions of the two different materials exposed on the other mating surface. In this example, the at least two different materials used for the hybrid bonding include a conductive material (e.g., copper) and an insulative material (e.g., a dielectric). Thus, as shown in FIG. 1, the first die 102 has a first surface 114 that is hybrid bonded to (e.g., directly abuts and is chemically bonded to) a second surface 116 of the second die 104. Further, as shown in the illustrated example, the mating surfaces 114, 116 include mating first and second conductive pads 118, 120 and mating portions of first and second dielectric materials 122, 124.

As represented in the illustrated example of FIG. 1, the first semiconductor die 102 includes a first bulk semiconductor region 126 (e.g., a first base substrate), a first active component region 128 (e.g., a first front-end-of-line (FEOL) region), and a first metallization region 130 (e.g., a first back-end-of-line (BEOL) region). Similarly, the second die 104 includes a second bulk semiconductor region 132 (e.g., a second base substrate), a second active component region 134 (e.g., a second front-end-of-line (FEOL) region), and a second metallization region 136 (e.g., a second back-end-of-line (BEOL) region).

The bulk semiconductor regions 126, 132 correspond to a block of semiconductor material (e.g., silicon) that serves as the starting point for the fabrication of the corresponding active component regions 128, 134 thereon followed by the fabrication of the corresponding metallization regions 130, 136. In other words, the bulk semiconductor regions 126, 132 correspond to portions of semiconductor wafers that have been processed to produce the resulting dies 102, 104.

The active component regions 128, 134 include active components (e.g., transistors) and associated structures that provide the basis for the functionality of the integrated circuits provided in the respective semiconductor dies 102, 104. The functionality of the example dies 102, 104 includes any suitable functionality (e.g., processing, memory, etc.).

The metallization regions 130, 136 include alternating layers of dielectric material and layers of metal that have been patterned to define interconnects (e.g., wiring) that electrically couple the transistors in the active component regions to fabricate complete circuits within the respective semiconductor dies 102, 104. More particularly, the layers of metal are patterned to define tracing, routing, pads, and/or other metal features in a given layer that are to form portions of the interconnects. The different metal features in a given metal layer are electrically coupled to other metal features in adjacent metal layers by way of conductive vias extending transversely through the intervening layer(s) of dielectric material. For purposes of simplicity and clarity, the metallization regions 130, 136 are shown as blocks of dielectric material 122, 124 with only the outermost metal layer being represented by the presence of the contact pads 118, 120. That is, in this example, the outermost metal layer of the metallization regions 130, 136 defines the mating surfaces 114, 116 of the respective dies 102, 104 that are hybrid bonded together. A more detailed representation and discussion of the metallization regions 130, 136 is provided below in connection with FIG. 2.

The chemical bonding (e.g., copper-to-copper bonding) of the contact pads 118, 120 along the mating surfaces 114, 116 of the first and second dies 102, 104 enables the electrical coupling of the two dies. Further, in some examples, the first die 102 includes one or more through-silicon vias 138 that extend through the first bulk semiconductor region 126 to electrically couple the circuitry within the two dies 102, 104 to external components by way of the second contacts 112.

As mentioned above, conductive features (e.g., pads, traces, etc.) in adjacent metal layers are electrically coupled with conductive vias extending through the intervening layer of dielectric material. Typically, such vias extend through only one dielectric layer to electrically couple two directly adjacent metal layers. When metal layers that are spaced farther apart need to be electrically coupled, a stack of multiple vias may be employed with each successive via in the stack extending through each successive dielectric layer with an intervening conductive pad in the metal layer between adjacent vias. Conductive vias typically extend through only one dielectric layer because the overall metallization regions 130, 136 are fabricated one layer at a time. That is, a dielectric layer is added, openings for conductive vias are provided through the dielectric layer, the openings are filled with conductive material to define the conductive vias, and then a metal layer is patterned on top. After the metal layer is complete, the process can repeat with another dielectric layer into which additional conductive vias are added followed by another metal layer. This process can repeat to produce as many alternating dielectric and metal layers as needed with each successive metal layer electrically coupled to the previous by the conductive vias through the intervening dielectric layers.

Although conductive vias typically extend through only one dielectric layer, in examples disclosed herein, some conductive vias (referred to herein as multi-layer vias) can extend directly through multiple dielectric layers to electrically couple metal layers that are not directly adjacent (e.g., there is one or more other metal layers between the metal layers being directly coupled). An example multi-layer via 140 is represented in the first metallization region 130 of the first die 102 of FIG. 1. In this example, the multi-layer via 140 extends through the entire thickness of the metallization region 130. That is, the multi-layer via 140 extends through all intermediate dielectric layers in the region 130. In other examples, the multi-layer via 140 extends through less than all (but at least two) dielectric layers. Although only one multi-layer via 140 is shown in FIG. 1, in other examples, the first die 102 includes more than one multi-layer via 140. In some such examples, different ones of the multi-layer vias 140 are different sizes (e.g., extend through different numbers of dielectric layers). Further, in some examples, the second die 104 additionally or alternatively includes one or more multi-layer via 140. In some examples, both of the dies 102, 104 include multi-layer vias that are directly coupled to corresponding ones of the contact pads 118, 120 at the interface between the two dies 102, 104.

FIG. 2 is a cross-sectional view of a portion of an example semiconductor die 200 constructed in accordance with teachings disclosed herein. The example die 200 of FIG. 2 may be used to implement either of the example dies 102, 104 of FIG. 1. As shown in the illustrated example, the die 200 includes a bulk semiconductor region 202 (e.g., a base substrate), an active component region 204 (e.g., a FEOL region), and a metallization region 206 (e.g., a BEOL region). The different regions 202, 204, 206 of the example die 200 of FIG. 2 can be the same or similar to the respective bulk semiconductor regions 126, 132, active component regions 128, 134, and the metallization regions 130, 136 of FIG. 1. Accordingly, the description of such regions 126, 128, 130, 132, 134, 136 outlined above applies equally to the corresponding regions 202, 204, 206 illustrated example of FIG. 2.

As shown in the illustrated example of FIG. 2, the metallization region 206 includes a plurality of dielectric layers 208, 209, 210, 211, 212, 213, 214, 215 that separate (e.g., are interleaved with) a plurality of metal layers 216, 217, 218, 219, 220, 221, 222, 223. In this example, the semiconductor die 200 includes a first interconnect 224 defined by an arrangement of electrically connected conductive pads 226. More particularly, as shown in the illustrated example, a separate conductive pad 226 is included in each of the metal layers 216-223 with each adjacent pair of conductive pads 226 electrically coupled by a conductive via 228 extending through the dielectric layer 208-215 between the corresponding adjacent pairs of metal layers 216-223. Inasmuch as the conductive vias 228 are located within the dielectric layers 208-215, the dielectric layers 208-215 are also referred to herein as via layers. In this example, the conductive pads 226 and intervening conductive vias 228 are arranged in a vertical line. However, other arrangements are possible. For instance, in some examples, one or more of the conductive pads 226 may be coupled to a corresponding conductive trace that extends laterally along the associated metal layer 216-223 to a different location (e.g., where another conductive pad 226 may be located and which is electrically coupled to an associated conductive via 228 in the next dielectric layer 208-215).

In some examples, the area(s) within the metal layers 216-223 that do not include any metal features (e.g., the area(s) laterally outside and/or between the conductive pads 226 within a given metal layer) are filled with an interlayer dielectric (ILD) 230. In some examples, the ILD 230 is different from the material in the dielectric layers 208-215. In other examples, the ILD 230 includes the same material used in the dielectric layers 208-215. In some such examples, each layer of ILD 230 and the dielectric layer 208-215 directly above each such layer of ILD 230 are integral portions of a single layer of dielectric material that is added in a single fabrication process.

As represented in FIG. 2, the metal layers 216-223 farther away from the active component region 204 are often thicker than layers closer to the active component region 204. Further, as represented in the illustrated example, metal features (e.g., the conductive pads 226) in the different metal layers 216-223 get larger (e.g., have a greater width) the farther away the metal layers (and associated features) are from the active component region 204. In some cases, the conductive vias 228 that electrically couple adjacent ones of the conductive pads 226 also get larger the farther away the conductive vias 228 are from the active component region 204. However, as shown in the illustrated example, the conductive vias 228 often remain significantly smaller than the conductive pads 226 (or other metal features) to which the vias 228 are coupled in the metal layers 216-223 farther away from the active component region 204.

The size difference between conductive vias 228 and adjacent conductive pads 226 is often most pronounced at the uppermost (e.g., outermost) metal layer (e.g., the eighth metal layer 223 in the illustrated example). The small conductive vias 228, relative to the adjacent conductive pads 226 (especially near the outer surface 232), can limit the current carrying capability of the associated interconnect 224. Furthermore, this problem can be exacerbated as the pitch continues to decrease. Moreover, this problem can be further exacerbated in dies that are to be hybrid bonded together because the uppermost (e.g., outermost) conductive pads 226 are often relatively large to enable reliable hybrid bonds (e.g., copper-to-copper bonds) between mating pads. That is, in situations of hybrid bonding, the size difference between the conductive vias 228 and the outermost conductive pad 226 is especially pronounced. As noted above, FIG. 2 is an example implementation of either of the dies 102, 104 of FIG. 1 that are hybrid bonded together. Thus, the top surface 232 of the eighth metal layer 223 in FIG. 2 corresponds to the mating surface 114, 116 of either of the dies 102, 104 shown in FIG. 1. In other words, in this example, the uppermost conductive pad 226 in the eighth metal layer 223 in FIG. 2 corresponds to one of the contact pads 118, 120 shown in FIG. 1.

In some examples, to reduce the negative effects of a relatively small conductive via 228 adjacent to a relatively large conductive pad 226 (e.g., at the outer surface 232), a multi-layer via is employed. Specifically, the left side of FIG. 2 illustrates a second example interconnect 234 that is similar to the first interconnect 224 except for an example multi-layer via 236 that extends through the three uppermost dielectric layers 213-215 as well as the two intervening metal layers 221, 222. That is, the example multi-layer via 236 directly electrically couples (e.g., extends continuously between) two conductive pads 226 in the fifth and eighth metal layers 220, 223. As shown in the illustrated example, the second interconnect 234 is identical to the first interconnect 224 below the fifth metal layer 220 (e.g., with a series of conductive pads 226 electrically coupled by intervening conductive vias 228). However, as discussed above for the first interconnect 224, the size and/or arrangement of the conductive pads 226 and/or conductive vias 228 in the second interconnect 234 can be modified in any suitable manner.

As noted above, the multi-layer via 236 of the illustrated example extends through three dielectric layers 213-215 and two metal layers 221, 222. In other examples, the multi-layer via 236 extends through only two dielectric layers and one metal layer. In other examples, the multi-layer via 236 extends through more than three dielectric layers and more than two metal layers. Further, although the multi-layer via 236 has an uppermost end that is directly below the uppermost metal layer 223 in FIG. 2, in other examples, the uppermost end of the multi-layer via 236 can be located at any other suitable layer. In other words, the multi-layer via 236 can extend between any two non-adjacent metal layers within the metallization region 206 of the example die 200. For purposes of distinction, the conductive vias 228 that extend through only one dielectric layer 213-215 (and no metal layers 216-223) are sometimes referred to herein as single-layer vias.

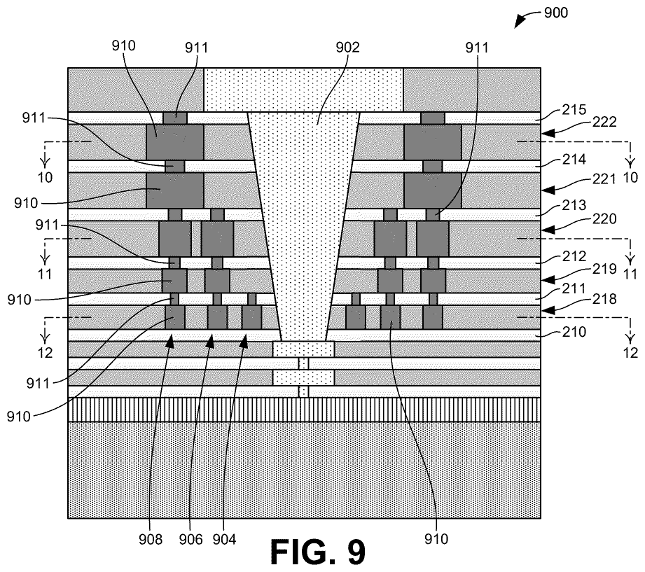

In the illustrated example, the multi-layer via 236 has a consistent width (e.g., diameter) along its full height (e.g., length). In other examples, the sidewalls of the multi-layer via 236 may be tapered such that the width at the top of the multi-layer via 236 is greater than the width at the bottom of the multi-layer via 236. That is, in some examples, the multi-layer via 236 has a generally conical shape. An example multi-layer via with tapered sidewalls is shown and discussed below in connection with FIG. 9.

As shown in the illustrated example, the multi-layer via 236 in the second interconnect 234 is much larger (e.g., wider) than the single-layer conductive via 228 directly beneath the uppermost conductive pad 226 in the first interconnect 224. As a result, the multi-layer via 236 significantly improves the current carrying capability of the second interconnect 234 relative to the first interconnect 224. The much larger diameter of the multi-layer via 236 is made possible because the multi-layer via 236 is manufactured during a separate fabrication process that is not subject to the same limitations as the layer-by-layer process during which the conductive vias 228 in the first interconnect 224 are fabricated (as well as other metal features within the metallization region 206). More particularly, the general process to fabricate the metallization region 206 (including a standard interconnect such as the first interconnect 224) involves adding the first dielectric layer 208, followed by adding the conductive vias 228 within the first dielectric layer 208, and then adding the conductive pads 226 (and/or any other metal features) within the first metal layer 216 on top of the first dielectric layer 208. This process is then repeated for each successive dielectric layer 209-215 followed by each subsequent metal layer 217-223.

The separate fabrication process for adding the multi-layer via 236 occurs only after the foregoing layer-by-layer process is completed up through the uppermost dielectric layer through which the multi-layer via is to extend (e.g., the uppermost dielectric layer 215 in the illustrated example). Specifically, this separate fabrication for the multi-layer via 236 involves etching through all metal layers and dielectric layers until reaching the conductive pad 226 defining the bottom end of the multi-layer via 236. That is, in the illustrated example of FIG. 2, the etching process to form an opening defining the location of the multi-layer via 236 includes etching through the top three dielectric layers 213-215 and the sixth and seventh metal layers 221, 222. However, when the etching process occurs, the metal layers to be etched will not include any metal features at the relevant location(s). Rather, the relevant location(s) will be filled with the ILD 230. It is only after the etch process is completed that the resulting opening will be plated with metal to define the conductive structure of the multi-layer via 236. In other words, during the etching process to fabricate the multi-layer via, only dielectric materials will be etched through with the underlying conductive pad 226 serving as an etch stop. The separate fabrication process to add the multi-layer via 236 enables continuous pitch scaling without limiting the thickness of the top metal layer (e.g., the eighth metal layer 223 in the illustrated example).

Although the relatively large diameter of the multi-layer via 236 enhances the ability of the second interconnect 234 to carry current, the fabrication of the multi-layer via 236 presents several challenges. Specifically, while the direction of the etching process can be reasonably controlled (e.g., to extend downwards from a defined opening in a mask provided overtop of the uppermost layer to be etched), this process is not perfect. More particularly, in some instances, the etch chemistry can interact with exposed portions of the dielectric material of the ILD 230 and/or the dielectric layers 213-215, thereby causing the etch chemistry to etch laterally outward beneath the etch mask. In some instances, this can damage the dielectric materials and/or even reach to adjacent metal features to cause corrosion of those features and/or potentially define a path for an open circuit and/or a short circuit when the opening is subsequently filled with metal during a plating process. To mitigate against these concerns, in this example, the semiconductor die 200 includes a lateral etch casing 238 (e.g., lateral guard ring, protective ring, lateral etch stop, etc.) defined by (e.g., including) one or more first conductive rings 240 placed around the multi-layer via 236 in the metal layers 221, 222 through which the multi-layer via 236 extends.

In some examples, the lateral etch casing 238 is also defined by (e.g., includes) one or more second conductive rings 242 placed around the multi-layer via 236 in the dielectric layers 213-215 through which the multi-layer via 236 extends. For purposes of distinction, the first conductive rings 240 (which are placed in respective ones of the metal layers) are referred to herein as metal layer rings, whereas the second conductive rings (placed in respective ones of the dielectric layers where the single-layer conductive vias 228 are located) are referred to herein as via layer rings. In some examples, the metal layer rings 240 and the via layer rings 242 are aligned and in direct contact to define a completely closed off (e.g., hermetic) wall extending the full height of the overall lateral etch casing 238. In some examples, metal layer rings 240 and via layer rings 242 are included in each corresponding metal layer and dielectric layer through which the multi-layer via 236 extends. Thus, in some examples, the entire structure of the lateral etch casing 238 (including each associated metal layer ring 240 and each associated via layer ring 242) extends through all the same layers of the metallization region 206 as the multi-layer via 236. In some examples, the lateral etch casing 238 includes metal layer rings 240 and/or via layer rings 242 in corresponding metal and/or dielectric layers beyond (e.g., above and/or below) those through which the multi-layer via 236 extends. Additionally or alternatively, in some examples, one or more of the metal layer rings 240 and/or one or more of the via layer rings 242 are omitted from a corresponding layer through which the multi-layer via 236 extends.

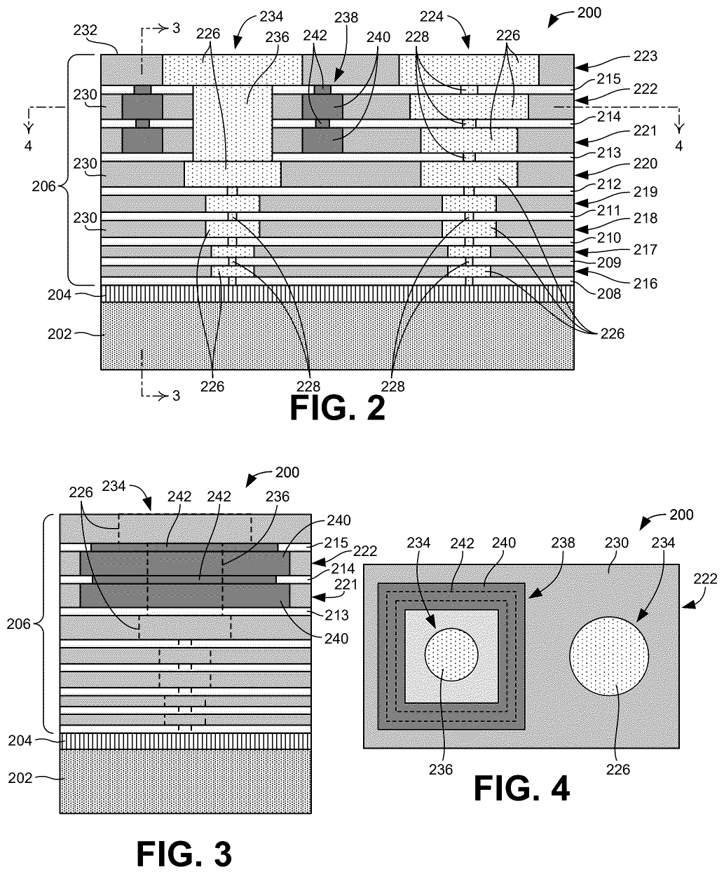

FIG. 3 is a cross-sectional side view of the example die 200 of FIG. 2 taken along the line 3-3 that passes through the lateral etch casing 238. In FIG. 3, an outline of the second interconnect 234 is represented in dashed lines for purposes of illustration. FIG. 4 is a cross-sectional top view of the example die 200 of FIG. 2 taken along the line 4-4 that extends parallel to and through the seventh metal layer 222. As noted above and shown in the illustrated example, each of the metal layer rings 240 are defined in respective ones of the metal layers 221, 222 through which the multi-layer via 236. In some examples, the metal layer rings 240 are added during the same fabrication process as when the conductive pads 226 in the corresponding metal layer 221, 222 are added for the first interconnect 224. Accordingly, in some examples, the metal layer rings 240 are made of the same conductive material (e.g., copper) as the conductive pads 226. In other words, the different shading of the metal layer rings 240 relative to other metal features shown in the illustrated example is for purposes of explanation to visually distinguish the metal layer rings 240 and is not intended to imply that the metal layer rings 240 must be composed of a different material than the interconnects 224, 234.

As shown in FIG. 4, each of the metal layer rings 240 extends completely around the multi-layer via 236. However, in other examples, the rings 240 only partially surround the multi-layer via 236. For instance, in some examples, the rings 240 extend around only three sides of the multi-layer via 236. In some examples, the rings 240 are defined by two discrete portions that flank opposite sides of the multi-layer via 236. In some examples, the rings 240 extend around the multi-layer via 236, but include one or more gaps along the path of the ring 240. That is, in some examples, the rings 240 substantially encircle or substantially surround the multi-layer via 236. As used in this context, “substantially encircle” and “substantially surround” means at least 85% of fully encircling or surrounding (whether along one continuous path or in two or more discrete segments). In some examples, the rings 240 encircle or surround the multi-layer via by more than 85% (e.g., 90%, 95%, 100%). In some examples, the rings 240 encircle or surround the multi-layer via by less than 85% (e.g., 80%, 75%, 60%, 50%, 35%, etc.). In some examples where a ring 240 does not extend completely around the multi-layer via 236 in a given metal layer, the gaps or spaces in the ring 240 are filled with a corrosion resistant material (e.g., a non-metal etch stop material). In other examples, the gaps or spaces are filled with the ILD 230 that fills all spaces between metal features in the given metal layer.

In the illustrated example of FIGS. 2-4, the metal layer rings 240 are generally rectangular (e.g., square, defined by straight walls). However, in other examples, the rings 240 can have any other suitable shape (e.g., circular, oval, triangular, defined by curved walls, defined by a combination of straight and curved walls, etc.). Further, although both rings 240 are shown as having the same size and shape, in other examples, different ones of the rings 240 can have different shapes and/or different sizes (including the overall dimensions as well as the width of the rings measured between inner and outer sidewalls of each ring 240). In this example, a separate ring 240 is included in each metal layer 221, 222 through which the multi-layer via 236 extends. In other examples, the lateral etch casing 238 includes rings 240 in less than all of the layers through which the multi-layer via 236 extends. In the illustrated examples, the different rings 240 that make up the lateral etch casing 238 are the same size and are vertically aligned. In other examples, different ones of the rings 240 can be different sizes and/or at least partially offset relative to one another.

As noted above and shown in the illustrated example, the lateral etch casing 238 also includes one or more via layer rings 242 extending through the dielectric layer 214, 215. In this example, a different via layer ring 242 is provided immediately above each of the metal layer rings 240. In some examples, only some of the dielectric layers immediately above the metal layer rings 240 include the via layer rings 242 while the other dielectric layers omit the via layer rings 242. Additionally or alternatively, in some examples, a via layer ring 242 extends through the dielectric layer 213 immediately below the bottommost metal layer ring 240.

Whereas the metal layer rings 240 may be added in the same fabrication process as the conductive pads 226 in the same metal layer 216-223 are added, in some examples, the via layer rings 242 are added in the same fabrication process as the single-layer conductive vias 228 added above corresponding ones of the conductive pads 226. Thus, in such examples, the via layer rings 242 include the same material (e.g., copper) as the single-layer conductive vias 228 and the different shading in the figures is merely to distinguish the lateral etch casing 238 from other metal features.

As represented by dashed lines in FIG. 4, the via layer rings 242 extend completely around the multi-layer via 236. However, in some examples, the via layer rings 242 only partially surround the multi-layer via 236 as discussed above in connection with the metal layer rings 240. In some examples, the extent to which the via layer rings 242 extend around the multi-layer via 236 is the same as the extent to which the metal layer rings 240 extend around the multi-layer via 236. In other examples, the extent to which the via layer rings 242 extend around the multi-layer via 236 is different from (e.g., more than or less than) the extent to which the metal layer rings 240 extend around the multi-layer via 236. Further, in some examples, rather than being defined by a continuous ring of conductive material, in some examples, the via layer rings 242 are defined by a ring of spaced apart single-layer conductive vias (e.g., similar to the vias 228 discussed above). In some examples, the size and/or shape of the via layer rings 242 can be different than what is shown. In some examples, the size and shape of the via layer rings 242 corresponds to the size and shape of the metal layer rings 240. Thus, the various alternatives described above with respect to the metal layer rings 240 applies equally to the via layer rings 242. In some examples, the via layer rings 242 can have a different size and/or shape from the adjacent metal layer rings 240.

The lateral etch casing 238 serves to provide a barrier that contains the etch chemistry used to fabricate the opening for the multi-layer via 236 within the designated region for the multi-layer via 236. That is, in the event the etch chemistry begins to etch away dielectric material (e.g., either in the dielectric layers 208-215 or the ILD 230) in a lateral direction, the extent of such etching is limited by the metal material of the lateral etch casing 238. As a result, this prevents short circuits connected with other metal features within the die 200 and/or prevents corrosion of such metal features. While the etch chemistry may cause some corrosion of the lateral etch casing 238, this is not a concern because the etch casing 238 is not intended to carry power or signals like other metal features the lateral etch casing 238 serves to protect.

The first interconnect 224 has been shown and described as not including a multi-layer via for purposes of comparison with the second interconnect 224 that includes a multi-layer via 236. However, in some examples, the first interconnect 224 can be implemented with a multi-layer via similar to what has been described in connection with the second interconnect 224. In some such examples, the multi-layer via may surrounded by a corresponding lateral etch casing similar to the lateral etch casing 238 surrounding the multi-layer via 236 in the second interconnect 234. In some examples, at least one multi-layer via associated with at least one interconnect is not surrounded by a lateral etch casing.

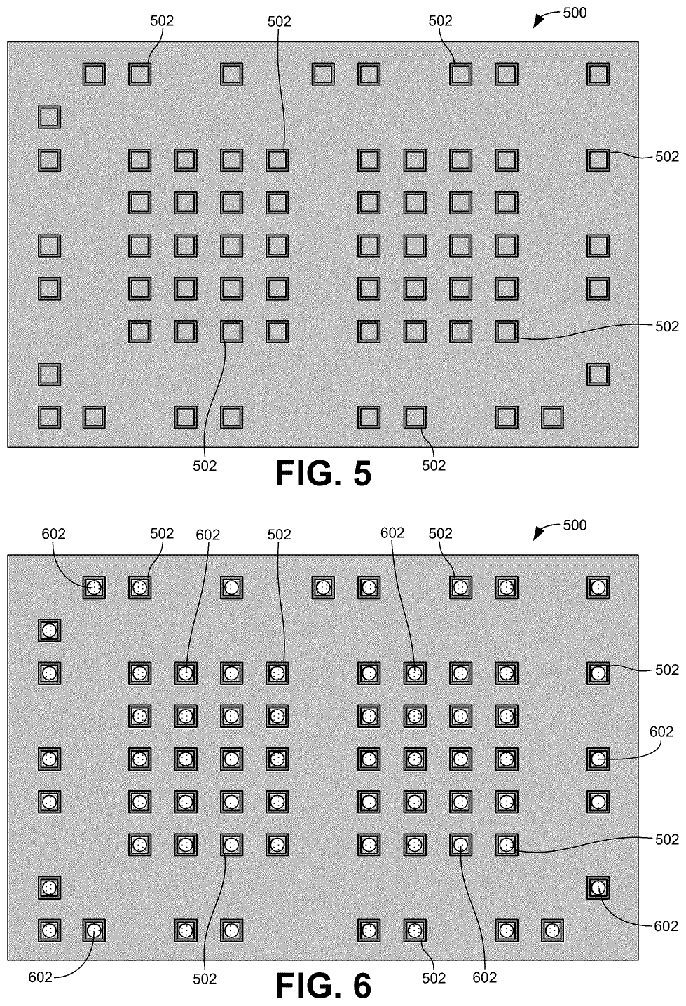

FIGS. 5 and 6 are top views of another example semiconductor die 500 respectively before and after the formation of an array of multi-layer vias 602 surrounded by corresponding lateral etch casings 502. The multi-layer vias 602 in FIG. 6 are the same as or similar to the example multi-layer vias 140, 236 of FIGS. 1-4. Likewise, the lateral etch casings 502 in FIGS. 5 and 6 are the same as or similar to the example lateral etch casing 238 of FIGS. 2-4. Accordingly, the description of the example multi-layer vias 140, 236 and the lateral etch casing 238 provided above applies equally to the multi-layer vias 602 and lateral etch casings 502 of FIGS. 5 and 6. As shown in the illustrated example, the lateral etch casings 502 are added before the multi-layer vias 602 are added (as shown in FIG. 5). More particularly, as discussed above and described in further detail below, the lateral etch casings 502 are provided during the layer-by-layer fabrication of the metallization region of the die 500 (e.g., the metallization regions 130, 136, 206 of FIGS. 1-4). After the metallization region has been fabricated up to the dielectric layer associated with the top of the multi-layer vias 602, an etching process is performed to provide openings for the multi-layer vias 602 in the metallization region. The resulting openings are then filled with a metal to define the multi-layer vias 602 (as shown in FIG. 6). Accordingly, in some examples, the locations of the multi-layer vias 602 are defined in advance and the lateral etch casings 502 are fabricated to surround those locations. In this manner, the lateral etch casings 502 are already in place when the etching process is to be performed to produce the multi-layer vias 602. As a result, the etch casings 502 prevent the etch chemistry from laterally spreading out and damaging exterior dielectric material, the corrosion of nearby metal features (not shown in FIGS. 5 and 6), and/or the formation of short or open circuits with such metal features.

In the illustrated example of FIG. 6, each one of the multi-layer vias 602 is surrounded by a corresponding lateral etch casing 502. However, in other examples, some of the multi-layer vias 602 are not associated with a corresponding lateral etch casing.

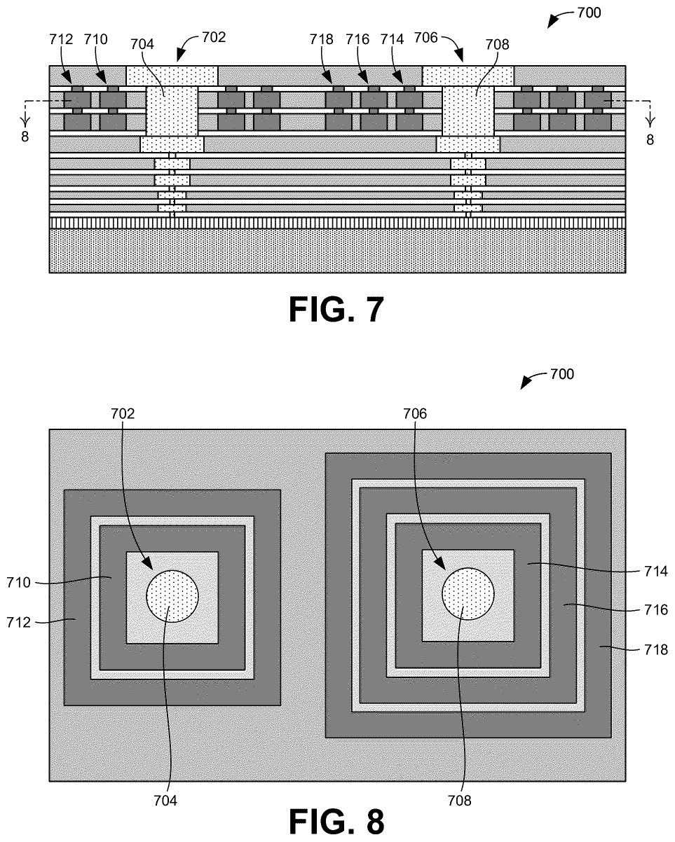

FIG. 7 is a cross-sectional view of another example semiconductor die 700 constructed in accordance with teaching disclosed herein. In this example, the die 700 includes a first interconnect 702 having a first multi-layer via 704 and a second interconnect 706 having a second multi-layer via 708. The example interconnects 702, 706 and associated multi-layer vias 704, 708 in FIG. 7 are the same as or similar to the example second interconnect 234 and associated multi-layer vias 140, 236, 602 of FIGS. 1-6. Accordingly, the description of such features provided above applies equally to the example interconnects 702, 706 and associated multi-layer vias 704, 708 of FIG. 7. In some examples, as shown, the different multi-layer vias 704, 708 are the same size, have the same depth (e.g., length), and pass through the same layers in the metallization region. In other examples, the different multi-layer vias 704, 708 can be different sizes, have different depths (e.g., lengths), and/or pass through different layers in the metallization region.

As shown in the illustrated example of FIG. 7, the multi-layer vias 704, 708 are surrounded by different lateral etch casings 710, 712, 714, 716, 718. FIG. 8 is a cross-sectional top view of the example die 700 of FIG. 7 taken along the line 8-8 that extends parallel to and through the different lateral etch casings 710, 712, 714, 716, 718 shown in FIG. 7. The example lateral etch casings 710, 712, 714, 716, 718 in FIGS. 7 and 8 are the same as or similar to the example lateral etch casings 238, 502 of FIGS. 2-6. Accordingly, the description of such features provided above applies equally to the example lateral etch casings 710, 712, 714, 716, 718 of FIGS. 7 and 8. The example shown in FIGS. 7 and 8 differs from the foregoing examples based on the number of lateral etch casings 710, 712, 714, 716, 718 surrounding each of the interconnects 702, 706. Specifically, in this example, the first multi-layer via 704 a first lateral etch casing 710 (e.g., an inner etch casing) that is surrounded by a second lateral etch casing 712 (e.g., an outer etch casing). Further, the second multi-layer via 704 is surrounded by three lateral etch casings including an inner lateral etch casing 714 (e.g., a third etch casing), an intermediate lateral etch casing 716 (e.g., a fourth etch casing) that surrounds the inner lateral etch casing 714, and an outer lateral etch casing (e.g., a fifth etch casing) that surrounds the intermediate lateral etch casing 716. In the illustrated example, the different lateral etch casings 710, 712, 714, 716, 718 are electrically isolated from one another. That is, in this example, dielectric material is located between the different lateral etch casings 710, 712, 714, 716, 718. In other examples, the different lateral etch casings 710, 712, 714, 716, 718 can be electrically coupled by metal extending therebetween.

The multiple lateral etch casings 710, 712, 714, 716, 718 surrounding a given multi-layer via 704, 708 can provide redundancy and/or increased reliability to prevent etch chemistry from spreading beyond the intended location for the multi-layer via. The number of lateral etch casings 710, 712, 714, 716, 718 can be any suitable number (e.g., 1, 2, 3, 4, etc.). For instance, in some examples, one of the multi-layer vias 704, 708, is surrounded by only one lateral etch casing while the other is surrounded by more than one lateral etch casing. In some examples, both multi-layer vias 704, 708 are surrounded by the same number of lateral etch casings which may be one or more than one.

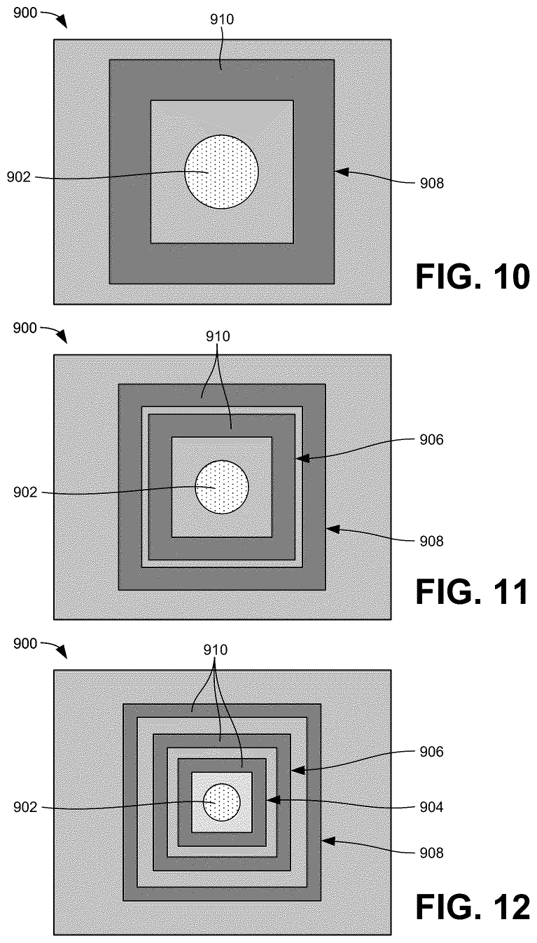

In some examples, the number of lateral etch casings surrounding a given multi-layer via can differ between different layers in the metallization region through which the multi-layer via extends. For instance, FIG. 9 illustrates another example semiconductor die 900 that includes a multi-layer via 902 that is surrounded by multiple lateral etch casings 904, 906, 908. FIGS. 10, 11, and 12 are cross-sectional top views of the example die 900 at different layers of the die 900. Specifically, FIG. 10 is a cross-sectional top view of the example die 900 taken along the line 10-10 that extends parallel to and through the uppermost metal layer 222 through which the multi-layer via 902 extends. FIG. 11 is a cross-sectional top view of the example die 900 taken along the line 11-11 that extends parallel to and through the middle metal layer 220 through which the multi-layer via 902 extends. FIG. 12 is a cross-sectional top view of the example die 900 taken along the line 12-12 that extends parallel to and through the bottommost metal layer 218 through which the multi-layer via 902 extends. Except as otherwise noted or made clear from the context, the multi-layer via 902 and the lateral etch casings 904, 906, 908 are the same as or similar to the multi-layer vias 140, 236, 602, 704, 708 and the lateral etch casings 238, 502, 710, 712, 714, 716, 718 of FIGS. 1-8. Accordingly, the description of such features provided above applies equally to the multi-layer via 902 and the lateral etch casings 904, 906, 908 of FIGS. 9-12.

In the illustrated example of FIGS. 9-12, the multi-layer via 902 extends through six dielectric layers 210-215 and five intervening metal layers 218-222. Further, as shown in the illustrated example, the multi-layer via 902 includes tapered walls such that the width (e.g., diameter) of the via 902 at the top (e.g., at the uppermost dielectric layer 215 through which the via 902 extends) is greater than the width (e.g., diameter) of the via 902 at the bottom (e.g., the lowermost dielectric layer 210 through which the via 902 extends).

In this example, the sizes and locations of the lateral etch casings 904, 906, 904 provide an overall barrier that generally follows the conical shape of the multi-layer via 902. More particularly, in this example, the first (inner) lateral etch casing 904 is limited to one metal layer 218 proximate the lower end of the multi-layer via 902 where the width of the via is relatively small. As a result, the first lateral etch casing 904 is relatively small and close to the multi-layer via 902. The second (intermediate) lateral etch casing 906 extends through three metal layers 218-220 including the metal layer 218 associated with the first lateral etch casing 904 and the next two metal layers 219-220 above. The second lateral etch casing 906 is outside (e.g., surrounds) the first lateral etch casing 904 and, thus, is farther away from the multi-layer via 902 at the bottom end of the via 902. However, as the width of the multi-layer via 902 expands towards the top of the via 902, the second lateral etch casing 906 gets closer to the sidewall of the via 902. The third (outer) lateral etch casing 906 extends through all the metal layers 218-222 that the multi-layer via 902 extends through at a location surrounding (e.g., outside) the other two lateral etch casings 904, 906. Due to the tapered shape of the multi-layer via 902, the third lateral etch casing 908 is farther away from the multi-layer via 902 at the bottom end than the third lateral etch casing 908 is away from the top end of the via 902.

The foregoing spacing of the lateral etch casings 904, 906, 908 relative to the multi-layer via 902 described above assumes that the different metal layer rings 910 (and the associated via layer rings 911) within each of the lateral etch casings 904, 906, 908 are arranged in vertical alignment as shown in the illustrated example (e.g., aligned in a direction normal to the dielectric layers 210-215 and metal layers 218-222 through which the multi-layer via 902 extends). However, in some examples, the different rings 910 within a given etch casing can be different sizes so that the profile of a given lateral etch casing follows a generally conical shape (which may or may not correspond to the conical shape of the multi-layer via 902). Furthermore, other arrangements are possible. That is, in some examples, the lateral etch casings do not define a shape generally corresponding to the multi-layer via 902 but can define any other suitable shape. For instance, multiple lateral etch casings of different heights (such as those shown in FIG. 12) may be implemented in connection with any of the example multi-layer vias 140, 236, 602, 704, 708 of FIGS. 1-8 (having a generally consistent width along a full length of the vias). Further, in some examples, the tallest lateral etch casing (e.g., the third etch casing 908 in the illustrated example) can be the closest etch casing to the multi-layer via 902 with the shortest etch casing (e.g., the first etch casing 904 in the illustrated example) being the farthest etch casing from the multi-layer via 902.

In some examples, rather than all of the lateral etch casings 904, 906, 908 having lower ends that are aligned in the bottom most metal layer 218 through which the multi-layer via 902 extends, the lateral etch casings 904, 906, 908 can lower ends in different layers to provide a staggered overlap along the length (e.g., height) of the via 902. For instance, in some examples, the first and second lateral etch casings 904, 906 may be arranged as shown in FIG. 9 (e.g., with lower ends in the third metal layer 218) while the third lateral etch casing is limited to the upper four metal layers 219-222 (e.g., it does not extend down to the third metal layer 218 as shown in the illustrated example). In other examples, two or more of the lateral etch casings 904, 906, 908 can have upper ends that are aligned in the same (e.g., uppermost) metal layer. Such variations in the metal layer in which the upper and lower ends of each lateral etch casing 904, 906, 908 are located can adjust the number of lateral etch casings within a given metal layer as well as the position of the etch casings relative the multi-layer via. Stated more generally, in some examples, an uppermost metal ring in a given lateral etch casing 904, 906, 908 surrounding a given multi-layer via 902 can be in a different metal layer from the uppermost metal ring of another lateral etch casing 904, 906, 908 surrounding the same multi-layer via 902. Additionally or alternatively, in some examples, a bottommost metal ring in a given lateral etch casing 904, 906, 908 surrounding a given multi-layer via 902 can be in a different metal layer from the bottommost metal ring of another lateral etch casing 904, 906, 908 surrounding the same multi-layer via 902.

As shown in FIGS. 9 and 10, the multi-layer via 902 is surrounded by only one lateral etch casing (e.g., the third etch casing 908) in the uppermost metal layer 222 through which the multi-layer via 902 extends. By contrast, as shown in FIGS. 9 and 11, the multi-layer via 902 is surrounded by two lateral etch casings (e.g., the second and third etch casings 906, 908) in the middle metal layer 220 through which the multi-layer via 902 extends. Further, as shown in FIGS. 9 and 12, the multi-layer via 902 is surrounded by all three lateral etch casings 904, 906, 908 in the bottommost metal layer 218 through which the multi-layer via 902 extends. In some examples, the greater number of etch casings are provided at the lower metal layers because metal features (including the rings 910) in those layers are smaller than is possible at the higher metal layers. As such, there may be a greater risk that etch chemistry would corrode through the finer (smaller) metal features in the lower layers giving rise to the need for additional etch casings at those layers. In other examples, a greater number of lateral etch casings may be provided in higher metal layers because the etching process begins at the upper layers such that there is more time for the etch chemistry to interact with the dielectric materials and/or metal features in the upper layers. In summary, example structure and arrangement of lateral etch casings are not limited to the particular examples shown in the figures but can be modified in any suitable manner to prevent the etching process from causing problems as outlined above.

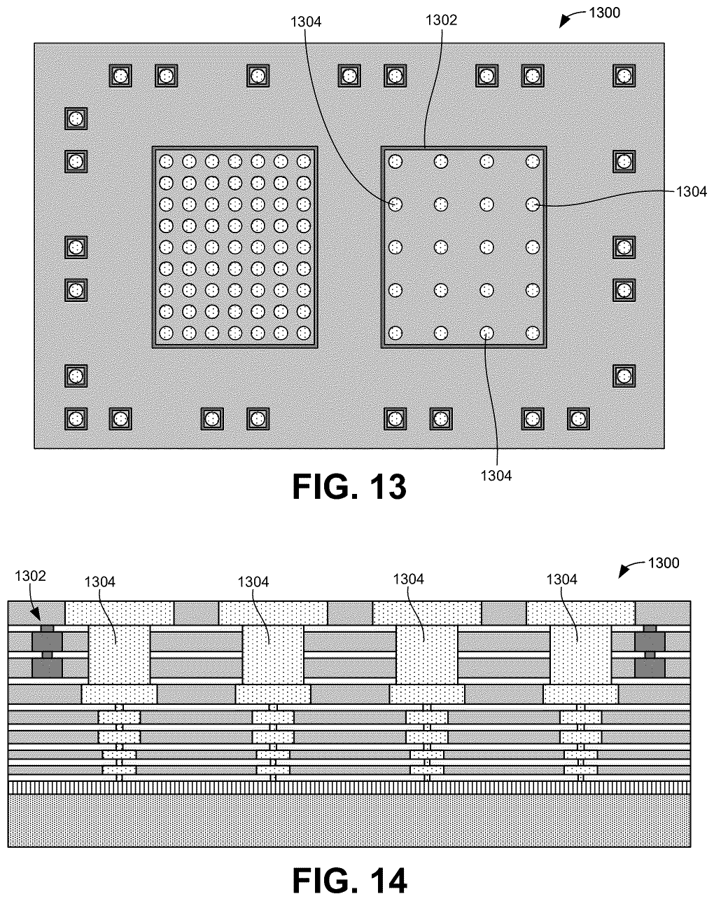

FIG. 13 is a top view of another example semiconductor die 1300 constructed in accordance with teachings disclosed herein. FIG. 14 is a cross-sectional side view of a portion of the example semiconductor die 1300 of FIG. 13. As shown in the illustrated example, the die 1300 includes a lateral etch casing 1302 that surrounds a group or plurality of multi-layer vias 1304. Except as otherwise noted or made clear form the context, the lateral etch casing 1302 and the multi-layer vias 1304 in FIGS. 13 and 13 may be the same as or similar to the multi-layer vias 140, 236, 602, 704, 708, 902 and the lateral etch casings 238, 502, 710, 712, 714, 716, 718, 904, 906, 908 of FIGS. 1-12. Accordingly, the description of such features provided above applies equally to the lateral etch casing 1302 and the multi-layer vias 1304 of FIGS. 13-14.

In the illustrated example of FIGS. 13 and 14, the lateral etch casing 1302 serves to prevent etch chemistry used to create the multi-layer vias 1304 from spreading outward beyond the etch casing 1302. However, because the multi-layer vias 1304 are not individually surrounded by different etch casings, there is the possibility that the etching process will result in the dielectric material between adjacent ones of the multi-layer vias 1304 being removed. This can result in short circuits between the adjacent multi-layer vias 1304. In this example, short circuits between the adjacent multi-layer vias 1304 within the lateral etch casing 1302 are not a concern because the adjacent multi-layer vias 1304 are associated with the same electric potential. That is, in some examples, the group of multi-layer vias 1304 that are all within the same lateral etch casing 1302 are all ground vias or all power vias.

The foregoing examples of the semiconductor dies 102, 104, 200, 500, 700, 900, 1300 including example multi-layer vias 140, 236, 602, 704, 708, 902, 1304 and associated example lateral etch casings 238, 502, 710, 712, 714, 716, 718, 904, 906, 908, 1302 of FIGS. 1-14 teach or suggest different features. Although each example semiconductor die 102, 104, 200, 500, 700, 900, 1300 disclosed above have certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

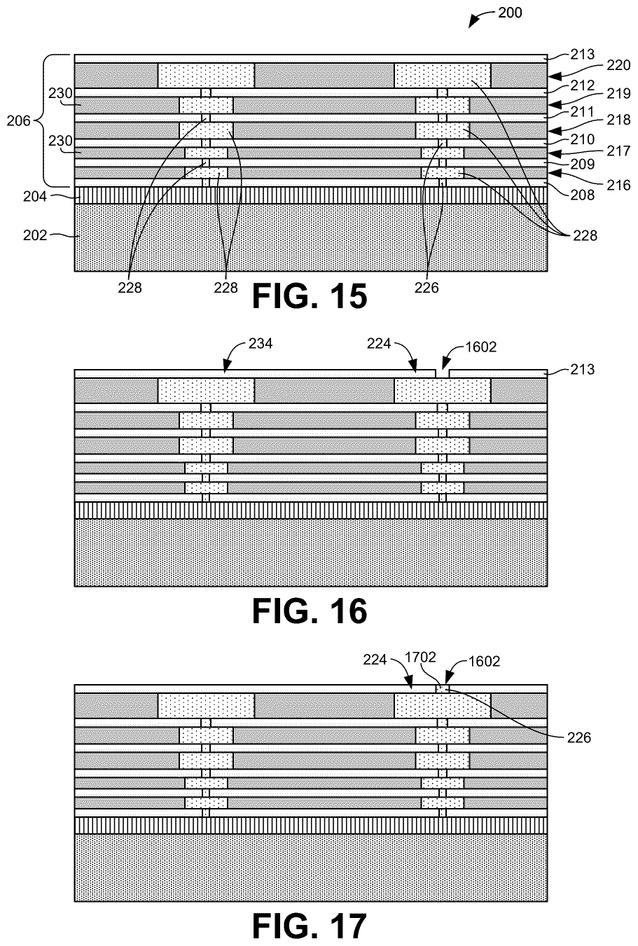

FIGS. 15-28 illustrate different stages in an example fabrication process to manufacture any one of the example semiconductor dies 102, 104, 200, 500, 700, 900, 1300 of FIG. 1-14 with one or more example lateral etch casings 238, 502, 710, 712, 714, 716, 718, 904, 906, 908, 1302 surrounding one or more example multi-layer vias 140, 236, 602, 704, 708, 902, 1304. For purposes of explanation, FIGS. 15-28 are shown and described with particular reference to the semiconductor die 200 of FIGS. 2-4.

FIG. 15 represents the stage of fabrication up through the first five metal layers 216-220 and the subsequent dielectric layer 213. The fabrication up to the point represented in FIG. 15 can follow any suitable processing operations. As mentioned above, such operations generally involve adding each successive dielectric layer 208-213 and metal layer 216-220 in an alternating sequence. After each dielectric layer 208-213 is added (and before the next metal layer 216-220 is added), openings are provided through the most recently added dielectric layer to expose portions of the metal (e.g., the conductive pads 226) in the immediately underlying metal layer. These openings are then filled (e.g., plated) with metal to define the conductive vias 228 that provide an electrical path up to the next metal layer.

In the illustrated example of FIG. 15, the uppermost dielectric layer (e.g., the sixth dielectric layer 213) corresponds to the first dielectric layer through which the multi-layer via 236 is to extend. Accordingly, the fabrication process begins departing from the typical approach because no via is added to the dielectric layer at this stage in the process. This is shown in FIG. 16, which represents the stage of fabrication after the uppermost dielectric layer 213 has been patterned (e.g., photolithographically patterned) to provide openings extending through the dielectric layer 213 to expose portions of the underlying metal. As shown in the illustrated example, one opening 1602 is provided in the dielectric layer 213 in connection with the first interconnect 224. However, no opening is provided through the dielectric layer 213 in connection with the second interconnect 234.

FIG. 17 represents the stage of fabrication following the deposition (e.g., plating) of a conductive material 1702 (e.g., metal, such as copper) within the opening 1602. In this example, the conductive material 1702 defines the next conductive via 228 defining the electrical path of the first interconnect 224.

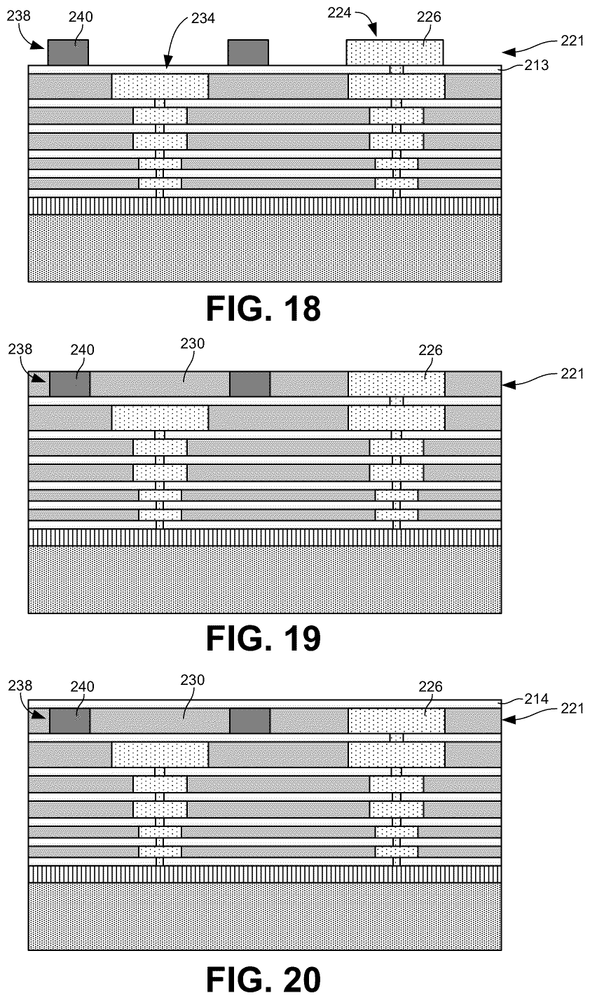

FIG. 18 represents the addition of metal features associated with the next metal layer 221 directly above the uppermost dielectric layer 213. In some examples, the metal features are added by first depositing a layer of metal across the entire exposed surface of the underlying dielectric layer 213. Thereafter, a photoresist is deposited over the layer of metal and photolithographically patterned to create openings in the photoresist that expose portions of the underlying layer of metal that are to be removed. The patterned photoresist then serves as a mask during an etching process that removes the exposed portions of metal. The photoresist is then removed and what remains are the metal features intended for the metal layer 221. In this example, the metal features include the next conductive pad 226 associated with the first interconnect 224 and the first metal layer ring 240 associated with the lateral etch casing 238 that is to surround the multi-layer via 236 in the second interconnect 234. Inasmuch as both the conductive pad 226 and the first ring 240 are produced in the same process, as discussed above, both metal features include the same metal (e.g., copper). As such, the different shading of the different metal features is merely intended to distinguish the lateral etch casing 238 from the metal features associated with the interconnects 224, 234. In some examples, if more than one lateral etch casing 238 is to surround the multi-layer via 236, then the layer of metal is patterned differently to define multiple rings 240 associated with the multiple lateral etch casings 238.

FIG. 19 represents the stage of fabrication following the addition of an interlayer dielectric (ILD) 230 within the uppermost metal layer 221 to fill the gaps between the different metal features (e.g., the conductive pad 226 and the first ring 240). FIG. 20 represents the stage of fabrication following the addition of the next dielectric layer 214 over the uppermost metal layer 221 (including the associated ILD 230). In some examples, the addition of the ILD 230 between the metal features in the underlying metal layer 221 and the addition of the next dielectric layer 213 that extends over top of the upper surfaces of the metal features are accomplished in a single process. In such examples, the same material is used for the ILD 230 and the dielectric layer 214.

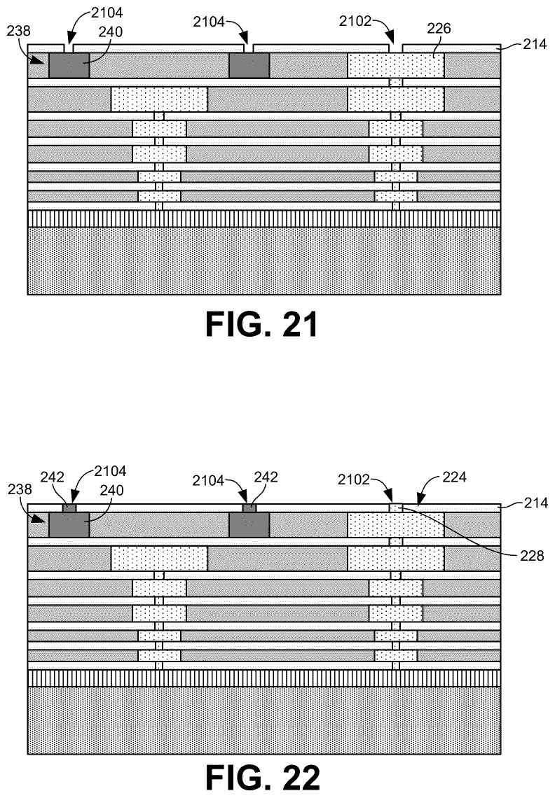

FIG. 21 represents the stage of fabrication after the uppermost dielectric layer (now the seventh dielectric layer 214) has been patterned to provide openings extending through the dielectric layer 214 to expose portions of the underlying metal. That is, FIG. 21 represents a similar process to that described above in connection with FIG. 16, except that in FIG. 21 there is one opening 2102 that exposes a portion of the underlying conductive pad 226 provided for the first interconnect 224 and additional openings 2104 that expose portion(s) of the underlying metal layer ring 240 of the lateral etch casing 238. As discussed above, in some examples, multiple openings 2104 can be located at different locations along the ring 240. In some examples, the openings 2104 can be elongate to extend along an elongate length of the ring 240. In some examples, a single opening 2104 that defines a complete ring is provided in the dielectric layer 214 in alignment with the underlying ring 240.

FIG. 22 represents the stage of fabrication following the deposition (e.g., plating) of a conductive material (e.g., metal, such as copper) within the openings 2102, 2104 in the uppermost dielectric layer 214. In this example, the conductive material corresponds to the next single-layer conductive via 228 defining the electrical path of the first interconnect 224 and the via layer ring 242 directly above the metal layer ring 240 associated with the lateral etch casing 238.

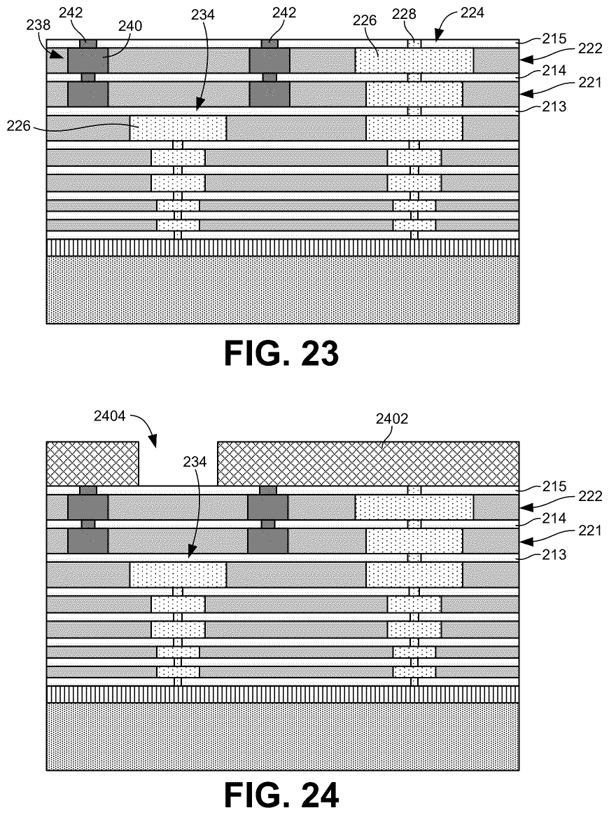

FIG. 23 represents the stage of fabrication following a repeat of the operations detailed in connection with FIGS. 18-22 to add the metal features in the next metal layer 222 followed by the addition of the next dielectric layer 215 with single-layer conductive vias 228, 242 provided therein. As shown in the illustrated example, the metal features in the uppermost metal layer 222 include another conductive pad 226 associated with the first interconnect 224 and a second ring 240 for the lateral etch casing 238.

At the stage of fabrication represented in FIG. 23, three dielectric layers 213-215 and the two intervening metal layers 221, 222 have been added above the uppermost conductive pad 226 associated with the second interconnect 234. However, as shown in the illustrated example, no metal has been provided within the area directly above this conductive pad 226 because this is where the multi-layer via 236 is to be located. In this example, the three dielectric layers 213-215 and the two intervening metal layers 221, 222 correspond to all the layers the multi-layer via 236 is to extend through. Accordingly, it is at this stage that the multi-layer via 236 can be added. Specifically, FIG. 24 represents the stage of fabrication following the addition of a mask 2402 (e.g., a photoresist that has been lithographically patterned) with an opening 2404 at the intended location of the multi-layer via 236. In some examples, where multiple multi-layer vias 236 are to be added, the mask 2402 includes multiple openings 2404.

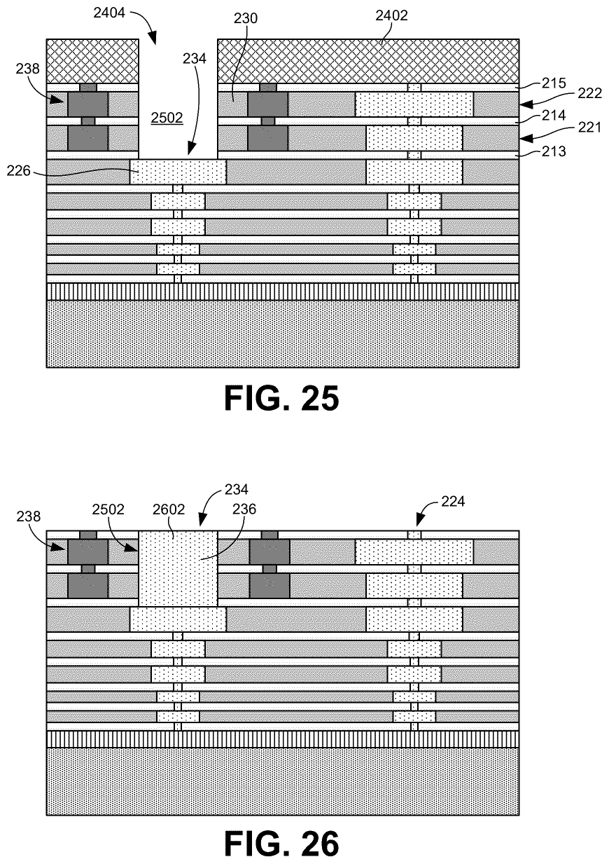

FIG. 25 represents the stage of fabrication following an etch process that removes dielectric material within the three dielectric layers 213-215 and the two intervening metal layers 221, 222 (e.g., the ILD 230 in the metal layers 221, 222) between the mask 2402 and the conductive pad 226 of the second interconnect 234 underlying the opening 2404 in the mask 2402. The resulting opening 2502 through the different layers 213, 214, 215, 221, 222 defines the shape of the resulting multi-layer via 236. In this example, the opening 2502 extends directly downward following a projection of the opening 2404 in the mask 2402. In other examples, the opening 2502 may have tapered sidewalls so as to narrow as it approaches the underlying conductive pad 226. While the general shape of the opening 2502 may be straight or tapered, in some instances, the etch chemistry may laterally eat into the dielectric materials underneath the mask 2402 (e.g., outside of the projection of the opening 2404 in the mask 2402). In some examples, depending on the nature and/or severity of the etch chemistry, the lateral expansion of the opening 2502 can be relatively significant. However, in this example, the lateral spread of the etch chemistry is contained by the lateral etch casing 238. That is, while the etch chemistry may eat away at the dielectric materials, the metal (e.g., copper) of the lateral etch casing 238 is much less sensitive to the etch chemistry. While there may be some corrosion of the lateral etch casing 238, it is unlikely to corrode all the way through the lateral etch casing 238, thereby preventing the spread of the etch chemistry. In situations where greater reliability is needed and/or the etch chemistry is particularly severe, more than one lateral etch casing 238 can be provided as discussed above.

FIG. 26 represents the stage of fabrication following the removal of the mask 2402 and subsequent filling of the opening 2502 with a conductive material 2602 to define the multi-layer via 236. As noted above, in some examples, if the etch chemistry resulted in the opening 2502 spreading out towards the lateral etch casing 238, the conductive material 2602 may be in contact with (e.g., electrically coupled to) the lateral etch casing 238. However, this is not a concern because the lateral etch casing 238 is electrically isolated from metal features (e.g., circuity) external to the lateral etch casing 238. In some examples, the lateral etch casing 238 is electrically coupled to ground. As noted above, the lateral etch casing 238 is fabricated during the same processes as the first interconnect 224 and, therefore, is composed of the same material (e.g., copper). By contrast, the conductive material 2604 for the multi-layer via 236 is added in a separate fabrication process (e.g., separate etching and plating process). Accordingly, in some examples, the conductive material 2604 is different from the material used for the lateral etch casing 238 and the first interconnect 224 (and/or different from the lower portion of the second interconnect 234 below the multi-layer via 236). In other examples, the conductive material 2604 may be the same as the material used for the other metal features shown in the illustrated example. Thus, the conductive material 2604 can be any suitable material (e.g., copper, tungsten, aluminum, etc.).

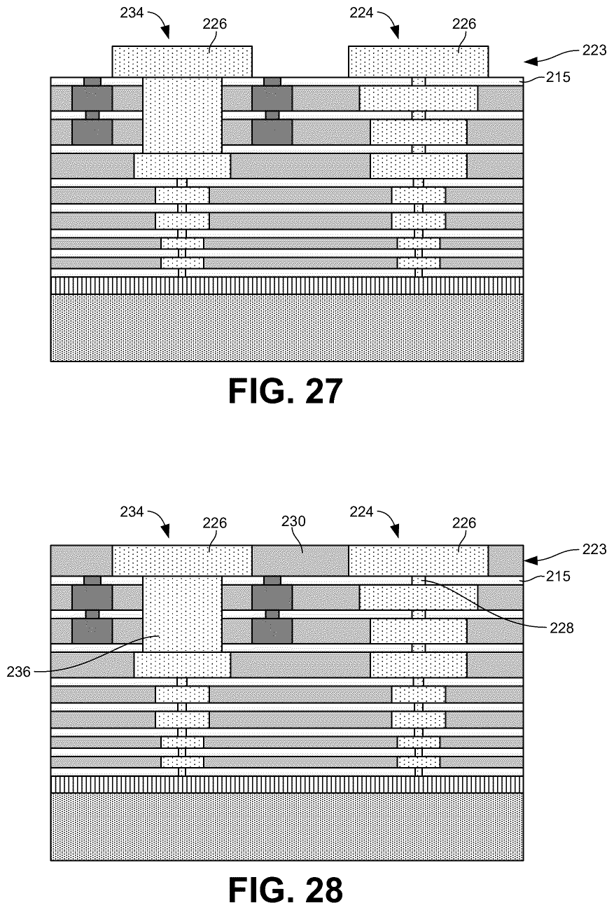

FIG. 27 represents the addition of metal features associated with the next metal layer 223 directly above the uppermost dielectric layer 215. In some examples, the metal features are added following the same process described above in connection with FIG. 18. In this example, the metal features correspond to the uppermost conductive pads 226 for both the first and second interconnects 224, 234. FIG. 28 represents the stage of fabrication following the addition of an interlayer dielectric (ILD) 230 within the uppermost metal layer 223 to fill the gaps between the different metal features (e.g., the conductive pads 226). This stage of the process corresponds to the completed die 200 as shown in FIG. 2.

As shown in the illustrated example of FIG. 28 (and discussed above in connection with FIG. 2), the multi-layer via 236 is directly coupled to the uppermost conductive pad 226 of the second interconnect 234, thereby providing a relatively large interfacing area between the conductive pad 226 and the via 236 (e.g., relative to the interfacing area between the uppermost conductive pad 226 of the first interconnect 224 and the immediately underlying single-layer conductive via 228). The relatively large size (e.g., diameter) of the multi-layer via 236 is made possible by adding the multi-layer via 236 later in the fabrication process after the layer-by-layer operations have already been completed up to the top layer (e.g., the eighth dielectric layer 215) through which the multi-layer via 236 extends. The relatively large size of the multi-layer via 236 is especially advantageous for use in hybrid bonding applications (as discussed above in connection with FIG. 1) because the multi-layer via 236 provides greater current carrying capability than the much smaller single-layer conductive via 228 immediately below the uppermost conductive pad 226 of the first interconnect 224. Although the multi-layer via 236 is described as advantageous in applications involving hybrid bonding of two separate dies, teachings disclosed herein are not limited to such applications. On the contrary, a multi-layer via 236 that is surrounded by one or more lateral etch casings 238 can be implemented in any semiconductor die employed for any suitable application.

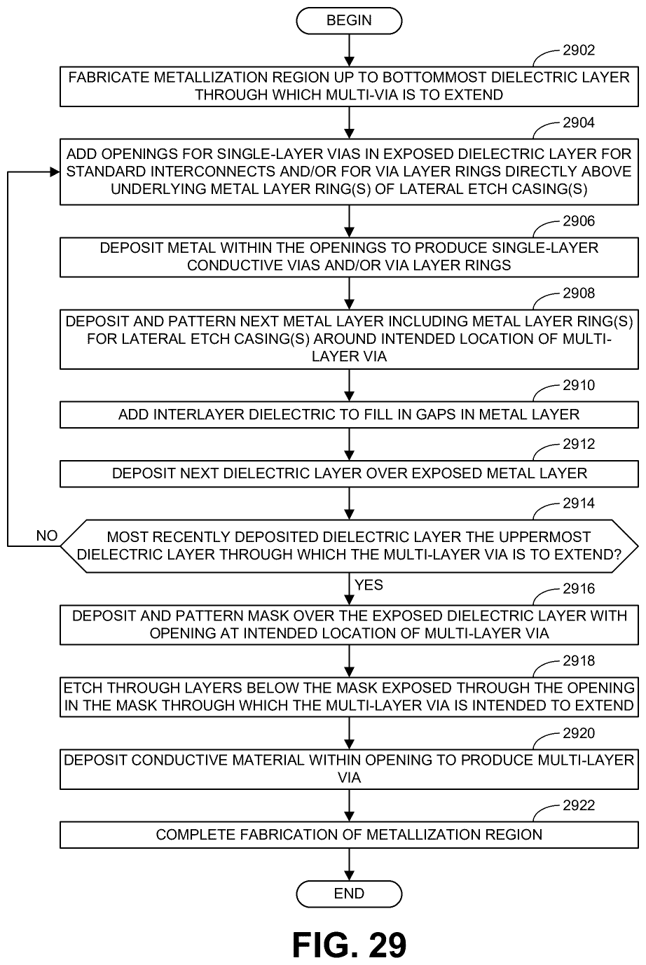

FIG. 29 is a flowchart representative of an example method of manufacturing any one of the example semiconductor dies 102, 104, 200, 500, 700, 900, 1300 of FIG. 1-28 with one or more of the example lateral etch casings 238, 502, 710, 712, 714, 716, 718, 904, 906, 908, 1302 surrounding one or more of the example multi-layer vias 140, 236, 602, 704, 708, 902, 1304. In some examples, some or all of the operations outlined in the example method of FIG. 29 are performed automatically by fabrication equipment that is programmed to perform the operations. For purposes of explanation, the flowchart of FIG. 29 is described with reference to the stages of fabrication represented in FIGS. 15-28, which correspond to the example semiconductor die 200 of FIG. 2. Although the example method of manufacture is described with reference to the flowchart illustrated in FIG. 29, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 29 begins at block 2902 by fabricating a metallization region (e.g., the metallization region 206) up to a bottommost dielectric layer (e.g., the sixth dielectric layer 213 in FIG. 2) through which a multi-via (e.g., the multi-layer via 236) is to extend. Completion of block 2902 corresponds to the stage of fabrication represented in FIG. 15.

At block 2904, the example method involves adding openings (e.g., the opening 1602 in FIG. 16 and the openings 2102, 2104 of FIG. 21) for single-layer vias (e.g., the conductive vias 228) in the exposed (e.g., currently uppermost) dielectric layer for standard interconnects (e.g., the first interconnect 224) and/or for via layer rings (e.g., the via layer rings 242) directly above underlying metal layer ring(s) (e.g., the metal layer rings 240) of lateral etch casing(s) (e.g., the lateral etch casing 238). Completion of a first iteration of block 2904 corresponds to the stage of fabrication represented in FIG. 16. Completion of a second iteration of block 2904 corresponds to the stage of fabrication represented in FIG. 21.

At block 2906, the example method involves depositing metal within the openings (e.g., the openings 1602, 2102, 2104) to produce single-layer conductive vias (e.g., the conductive vias 228) and/or via layer rings (e.g., the via layer ring 242). Completion of a first iteration of block 2906 corresponds to the stage of fabrication represented in FIG. 17. Completion of a second iteration of block 2902 corresponds to the stage of fabrication represented in FIG. 22.

At block 2908, the example method involves depositing and patterning a next metal layer (e.g., either of the sixth or seventh metal layers 221, 222 depending on the iteration of block 2908) including metal layer ring(s) 240 for lateral etch casing(s) 238 around the intended location of the multi-layer via 236. Completion of a first iteration of block 2908 corresponds to the stage of fabrication represented in FIG. 18.

At block 2910, the example method involves adding an interlayer dielectric (ILD) (e.g., the ILD 230) to fill in gaps in the metal layer (e.g., either of the sixth or seventh metal layers 221, 222 depending on the iteration of block 2910). Completion of a first iteration of block 2910 corresponds to the stage of fabrication represented in FIG. 19.

At block 2912, the example method involves depositing the next dielectric layer (e.g., either of the seventh or eighth metal layers 221, 222 depending on the iteration of block 2912). Completion of a first iteration of block 2912 corresponds to the stage of fabrication represented in FIG. 20.

At block 2914, the example method involves determining whether the most recently deposited dielectric layer (e.g., deposited at the last iteration of block 2912) is the uppermost dielectric layer through which the multi-layer via 236 is to extend. If not, the method returns to block 2904 to iterate through the process to add another metal layer including another ring 240 for the lateral etch casing(s) 238, followed by another dielectric layer. If the most recently deposited dielectric layer is the uppermost dielectric layer through which the multi-layer via 236 is to extend (e.g., the eighth dielectric layer 215 in FIG. 2), the process advances to block 2916. Completion of all iterations through blocks 2904-2914 corresponds to the stage of fabrication represented in FIG. 23.

At block 2916, the example method involves depositing and patterning a mask (e.g., the mask 2402) over the exposed dielectric layer (e.g., the dielectric layer 215) with an opening (e.g., the opening 2404) at the intended location of the multi-layer via 236. Completion of block 2916 corresponds to the stage of fabrication represented in FIG. 24.

At block 2918, the example method involves etching through the layers (e.g., the three uppermost dielectric layers 213-215 and the two intervening metal layers 221, 222) below the mask 2402 exposed through the opening 2404 in the mask 2402 through which the multi-layer via 236 is intended to extend. In some examples, the depth of the etch is limited by a conductive pad 226 that is aligned with the opening 2404 and below the multiple intervening layers to be etched away. Further, as discussed above, the lateral spread of the etch is limited by the lateral etch casing(s) 238 surrounding the intended location of multi-layer via 236 (corresponding to the location of the opening 2404). Completion of block 2918 corresponds to the stage of fabrication represented in FIG. 25.

At block 2920, the example method involves depositing (e.g., plating) conductive material (e.g., the conductive material 2604) within the opening 2404 to form the multi-layer via 236. In some examples, this can be done before removal of the mask 2402. In other examples, the plating process is done after removal of the mask 2402. Completion of block 2920 corresponds to the stage of fabrication represented in FIG. 26.

At block 2922, the example method involves completing fabrication of the metallization region 206. Completion of block 2922 corresponds to the stage of fabrication represented in FIG. 28, which corresponds to the completed semiconductor die 200 shown in FIG. 2. Thereafter, the example method of FIG. 29 ends.

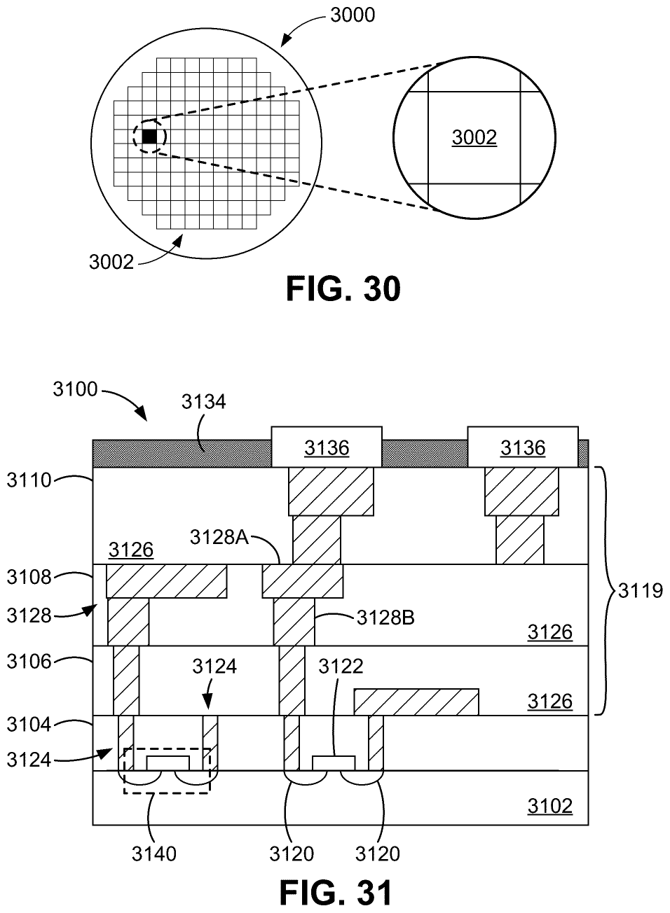

The example semiconductor dies 102, 104, 200, 500, 700, 900, 1300 disclosed herein may be included in any suitable electronic component. FIGS. 30-34 illustrate various examples of apparatus that may include or be included in the semiconductor dies 102, 104, 200, 500, 700, 900, 1300 disclosed herein.

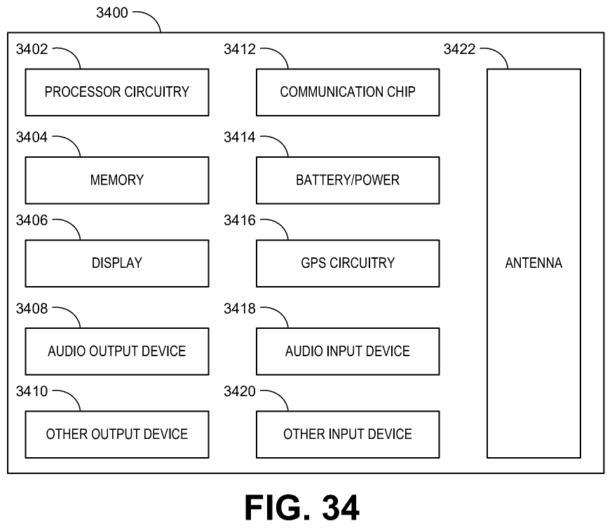

FIG. 30 is a top view of a wafer 3000 and dies 3002 that may correspond to any of the example semiconductor dies 102, 104, 200, 500, 700, 900, 1300 disclosed herein. The wafer 3000 includes semiconductor material and one or more dies 3002 having circuitry. Each of the dies 3002 may be a repeating unit of a semiconductor product. After the fabrication of the semiconductor product is complete, the wafer 3000 may undergo a singulation process in which the dies 3002 are separated from one another to provide discrete “chips.” The die 3002 includes one or more transistors (e.g., some of the transistors 3140 of FIG. 31, discussed below), supporting circuitry to route electrical signals to the transistors, passive components (e.g., traces, resistors, capacitors, inductors, and/or other circuitry), and/or any other components. In some examples, the die 3002 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 3002. For example, a memory array of multiple memory circuits may be formed on a same die 3002 as programmable circuitry (e.g., the processor circuitry 3402 of FIG. 34) and/or other logic circuitry. Such memory may store information for use by the programmable circuitry. The example semiconductor dies 102, 104, 200, 500, 700, 900, 1300 disclosed herein may be manufactured using a die-to-wafer assembly technique in which some dies are attached to a wafer 3000 that includes others of the dies, and the wafer 3000 is subsequently singulated.

FIG. 31 is a cross-sectional side view of an IC device 3100 that may be included in an IC package whose substrate includes one or more example lateral etch casings 238, 502, 710, 712, 714, 716, 718, 904, 906, 908, 1302 surrounding one or more example multi-layer vias 140, 236, 602, 704, 708, 902, 1304 constructed in accordance with any of the examples disclosed herein. One or more of the IC devices 3100 may be included in one or more dies 3002 (FIG. 30). The IC device 3100 may be formed on a die substrate 3102 (e.g., the wafer 3000 of FIG. 30) and may be included in a die (e.g., the die 3002 of FIG. 30). The die substrate 3102 may be a semiconductor substrate including semiconductor materials including, for example, n-type or p-type materials systems (or a combination of both). The die substrate 3102 may include, for example, a crystalline substrate formed using a bulk silicon or a silicon-on-insulator (SOI) substructure. In some examples, the die substrate 3102 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 3102. Although a few examples of materials from which the die substrate 3102 may be formed are described here, any material that may serve as a foundation for an IC device 3100 may be used. The die substrate 3102 may be part of a singulated die (e.g., the dies 3002 of FIG. 30) or a wafer (e.g., the wafer 3000 of FIG. 30).

The IC device 3100 may include one or more device layers 3104 disposed on and/or above the die substrate 3102. The device layer 3104 may include features of one or more transistors 3140 (e.g., metal oxide semiconductor field-effect transistors (MOSFETs)) formed on the die substrate 3102. The device layer 3104 may include, for example, one or more source and/or drain (S/D) regions 3120, a gate 3122 to control current flow between the S/D regions 3120, and one or more S/D contacts 3124 to route electrical signals to/from the S/D regions 3120. The transistors 3140 may include additional features not depicted for the sake of clarity, such as device isolation regions, gate contacts, and the like. The transistors 3140 are not limited to the type and configuration depicted in FIG. 31 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 3140 may include a gate 3122 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 3140 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 3140 along the source-channel-drain direction, the gate electrode may include a U-shaped structure that includes a bottom portion substantially parallel to the surface of the die substrate 3102 and two sidewall portions that are substantially perpendicular to the top surface of the die substrate 3102. In other examples, at least one of the metal layers that form the gate electrode may be a planar layer that is substantially parallel to the top surface of the die substrate 3102 and does not include sidewall portions substantially perpendicular to the top surface of the die substrate 3102. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 3120 may be formed within the die substrate 3102 adjacent to the gate 3122 of corresponding transistor(s) 3140. The S/D regions 3120 may be formed using an implantation/diffusion process or an etching/deposition process, for example. In the former process, dopants such as boron, aluminum, antimony, phosphorous, or arsenic may be ion-implanted into the die substrate 3102 to form the S/D regions 3120. An annealing process that activates the dopants and causes them to diffuse farther into the die substrate 3102 may follow the ion-implantation process. In the latter process, the die substrate 3102 may first be etched to form recesses at the locations of the S/D regions 3120. An epitaxial deposition process may then be carried out to fill the recesses with material that is used to fabricate the S/D regions 3120. In some implementations, the S/D regions 3120 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 3120 may be formed using one or more alternate semiconductor materials such as germanium or a group III-V material or alloy. In further examples, one or more layers of metal and/or metal alloys may be used to form the S/D regions 3120.

Electrical signals, such as power and/or input/output (I/O) signals, may be routed to and/or from the devices (e.g., transistors 3140) of the device layer 3104 through one or more interconnect layers disposed on the device layer 3104 (illustrated in FIG. 31 as interconnect layers 3106-3110). For example, electrically conductive features of the device layer 3104 (e.g., the gate 3122 and the S/D contacts 3124) may be electrically coupled with the interconnect structures 3128 of the interconnect layers 3106-3110. The one or more interconnect layers 3106-3110 may form a metallization stack (also referred to as an “ILD stack”) 3119 of the IC device 3100.

The interconnect structures 3128 may be arranged within the interconnect layers 3106-3110 to route electrical signals according to a wide variety of designs (in particular, the arrangement is not limited to the particular configuration of interconnect structures 3128 depicted in FIG. 31). Although a particular number of interconnect layers 3106-3110 is depicted in FIG. 31, examples of the present disclosure include IC devices having more or fewer interconnect layers than depicted.

In some examples, the interconnect structures 3128 may include lines 3128a and/or vias 3128b filled with an electrically conductive material such as a metal. The lines 3128a may be arranged to route electrical signals in a direction of a plane that is substantially parallel with a surface of the die substrate 3102 upon which the device layer 3104 is formed. For example, the lines 3128a may route electrical signals in a direction in and/or out of the page from the perspective of FIG. 31. The vias 3128b may be arranged to route electrical signals in a direction of a plane that is substantially perpendicular to the surface of the die substrate 3102 upon which the device layer 3104 is formed. In some examples, the vias 3128b may electrically couple lines 3128a of different interconnect layers 3106-3110 together.

The interconnect layers 3106-3110 may include a dielectric material 3126 disposed between the interconnect structures 3128, as shown in FIG. 31. In some examples, the dielectric material 3126 disposed between the interconnect structures 3128 in different ones of the interconnect layers 3106-3110 may have different compositions; in other examples, the composition of the dielectric material 3126 between different interconnect layers 3106-3110 may be the same.

A first interconnect layer 3106 (referred to as Metal 1 or “M1”) may be formed directly on the device layer 3104. In some examples, the first interconnect layer 3106 may include lines 3128a and/or vias 3128b, as shown. The lines 3128a of the first interconnect layer 3106 may be coupled with contacts (e.g., the S/D contacts 3124) of the device layer 3104.

A second interconnect layer 3108 (referred to as Metal 2 or “M2”) may be formed directly on the first interconnect layer 3106. In some examples, the second interconnect layer 3108 may include vias 3128b to couple the lines 3128a of the second interconnect layer 3108 with the lines 3128a of the first interconnect layer 3106. Although the lines 3128a and the vias 3128b are structurally delineated with a line within each interconnect layer (e.g., within the second interconnect layer 3108) for the sake of clarity, the lines 3128a and the vias 3128b may be structurally and/or materially contiguous (e.g., simultaneously filled during a dual-damascene process) in some examples.

A third interconnect layer 3110 (referred to as Metal 3 or “M3”) (and additional interconnect layers, as desired) may be formed in succession on the second interconnect layer 3108 according to similar techniques and/or configurations described in connection with the second interconnect layer 3108 or the first interconnect layer 3106. In some examples, the interconnect layers that are “higher up” in the metallization stack 3119 in the IC device 3100 (i.e., further away from the device layer 3104) may be thicker.

The IC device 3100 may include a solder resist material 3134 (e.g., polyimide or similar material) and one or more conductive contacts 3136 formed on the interconnect layers 3106-3110. In FIG. 31, the conductive contacts 3136 are illustrated as taking the form of bond pads. The conductive contacts 3136 may be electrically coupled with the interconnect structures 3128 and configured to route the electrical signals of the transistor(s) 3140 to other external devices. For example, solder bonds may be formed on the one or more conductive contacts 3136 to mechanically and/or electrically couple a chip including the IC device 3100 with another component (e.g., a circuit board). The IC device 3100 may include additional or alternate structures to route the electrical signals from the interconnect layers 3106-3110; for example, the conductive contacts 3136 may include other analogous features (e.g., posts) that route the electrical signals to external components.

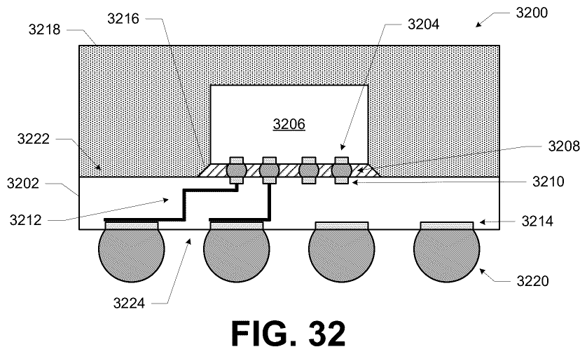

FIG. 32 is a cross-sectional view of an example IC package 3200 that may include one or more example lateral etch casings 238, 502, 710, 712, 714, 716, 718, 904, 906, 908, 1302 surrounding one or more example multi-layer vias 140, 236, 602, 704, 708, 902, 1304 disclosed herein. The package substrate 3202 may include a dielectric material, and may have conductive pathways extending through the dielectric material between upper and lower faces 3222, 3224, and/or between different locations on the upper face 3222, and/or between different locations on the lower face 3224. These conductive pathways may take the form of any of the interconnects 3128 discussed above with reference to FIG. 31.

The IC package 3200 may include a die 3206 (e.g., corresponding to any one of the example semiconductor dies 102, 104, 200, 500, 700, 900, 1300 disclosed herein) coupled to the package substrate 3202 via conductive contacts 3204 of the die 3206, first-level interconnects 3208, and conductive contacts 3210 of the package substrate 3202. The conductive contacts 3210 may be coupled to conductive pathways 3212 through the package substrate 3202, allowing circuitry within the die 3206 to electrically couple to various ones of the conductive contacts 3214 (or to other devices included in the package substrate 3202, not shown). The first-level interconnects 3208 illustrated in FIG. 32 are solder bumps, but any suitable first-level interconnects 3208 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

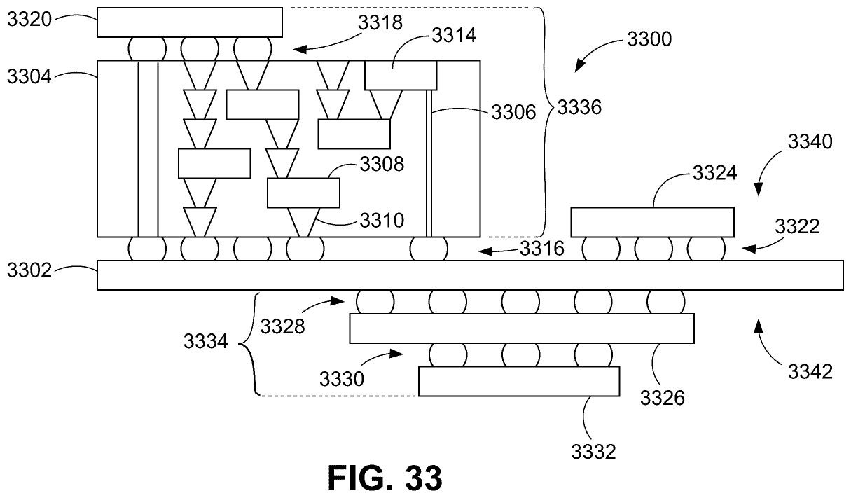

In some examples, an underfill material 3216 may be disposed between the die 3206 and the package substrate 3202 around the first-level interconnects 3208, and/or a mold compound 3218 may be disposed around the die 3206 and in contact with the package substrate 3202. In some examples, the underfill material 3216 may be the same as the mold compound 3218. Example materials that may be used for the underfill material 3216 and the mold compound 3218 are epoxy mold materials, as suitable. Second-level interconnects 3220 may be coupled to the conductive contacts 3214. The second-level interconnects 3220 illustrated in FIG. 32 are solder balls (e.g., for a ball grid array arrangement), but any suitable second-level interconnects 3220 may be used (e.g., pins in a pin grid array arrangement or lands in a land grid array arrangement). The second-level interconnects 3220 may be used to couple the IC package 3200 to another component, such as a circuit board (e.g., a motherboard), an interposer, or another IC package, as known in the art and as discussed below with reference to FIG. 33.

In FIG. 32, the IC package 3200 is a flip chip package, and includes one or more example lateral etch casings 238, 502, 710, 712, 714, 716, 718, 904, 906, 908, 1302 surrounding one or more example multi-layer vias 140, 236, 602, 704, 708, 902, 1304 in the die 3206. The die 3206 may take the form of any of the examples of the die discussed herein (e.g., may include any of the examples of the IC device 3100 including any of the example semiconductor dies 102, 104, 200, 500, 700, 900, 1300).

Although the IC package 3200 illustrated in FIG. 32 is a flip chip package, other package architectures may be used. For example, the IC package 3200 may be a ball grid array (BGA) package, such as an embedded wafer-level ball grid array (eWLB) package. In another example, the IC package 3200 may be a wafer-level chip scale package (WLCSP) or a panel fanout (FO) package. Although a single die 3206 is illustrated in the IC package 3200 of FIG. 32, an IC package 3200 may include multiple dies 3206 (e.g., the two dies 102, 104 hybrid bonded together as shown in FIG. 1). An IC package 3200 may include additional passive components, such as surface-mount resistors, capacitors, and/or inductors disposed on the first face 3222 or the second face 3224 of the package substrate 3202. More generally, an IC package 3200 may include any other active and/or passive components known in the art.

FIG. 33 is a cross-sectional side view of an IC device assembly 3300 that may include one or more of the example semiconductor dies 102, 104, 200, 500, 700, 900, 1300 disclosed herein. The IC device assembly 3300 includes a number of components disposed on a circuit board 3302 (which may be, for example, a motherboard). The IC device assembly 3300 includes components disposed on a first face 3340 of the circuit board 3302 and an opposing second face 3342 of the circuit board 3302; generally, components may be disposed on one or both faces 3340 and 3342.

In some examples, the circuit board 3302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 3302. In other examples, the circuit board 3302 may be a non-PCB substrate.

The IC device assembly 3300 illustrated in FIG. 33 includes a package-on-interposer structure 3336 coupled to the first face 3340 of the circuit board 3302 by coupling components 3316. The coupling components 3316 may electrically and mechanically couple the package-on-interposer structure 3336 to the circuit board 3302, and may include solder balls (as shown in FIG. 33), male and female portions of a socket, an adhesive, an underfill material, and/or any other suitable electrical and/or mechanical coupling structure.

The package-on-interposer structure 3336 may include an IC package 3320 coupled to an interposer 3304 by coupling components 3318. The coupling components 3318 may take any suitable form for the application, such as the forms discussed above with reference to the coupling components 3316. Although a single IC package 3320 is shown in FIG. 33, multiple IC packages may be coupled to the interposer 3304; indeed, additional interposers may be coupled to the interposer 3304. The interposer 3304 may provide an intervening substrate used to bridge the circuit board 3302 and the IC package 3320. The IC package 3320 may be or include, for example, a die (the die 3002 of FIG. 30), an IC device (e.g., the IC device 3100 of FIG. 31), or any other suitable component. Generally, the interposer 3304 may spread a connection to a wider pitch or reroute a connection to a different connection. For example, the interposer 3304 may couple the IC package 3320 (e.g., a die) to a set of BGA conductive contacts of the coupling components 3316 for coupling to the circuit board 3302. In the example illustrated in FIG. 33, the IC package 3320 and the circuit board 3302 are attached to opposing sides of the interposer 3304; in other examples, the IC package 3320 and the circuit board 3302 may be attached to a same side of the interposer 3304. In some examples, three or more components may be interconnected by way of the interposer 3304.

In some examples, the interposer 3304 may be formed as a PCB, including multiple metal layers separated from one another by layers of dielectric material and interconnected by electrically conductive vias. In some examples, the interposer 3304 may be formed of an epoxy resin, a fiberglass-reinforced epoxy resin, an epoxy resin with inorganic fillers, a ceramic material, or a polymer material such as polyimide. In some examples, the interposer 3304 may be formed of alternate rigid or flexible materials that may include the same materials described above for use in a semiconductor substrate, such as silicon, germanium, and other group III-V and group IV materials. The interposer 3304 may include metal interconnects 3308 and vias 3310, including but not limited to through-silicon vias (TSVs) 3306. The interposer 3304 may further include embedded devices 3314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3304. The package-on-interposer structure 3336 may take the form of any of the package-on-interposer structures known in the art.

The IC device assembly 3300 may include an IC package 3324 coupled to the first face 3340 of the circuit board 3302 by coupling components 3322. The coupling components 3322 may take the form of any of the examples discussed above with reference to the coupling components 3316, and the IC package 3324 may take the form of any of the examples discussed above with reference to the IC package 3320.

The IC device assembly 3300 illustrated in FIG. 33 includes a package-on-package structure 3334 coupled to the second face 3342 of the circuit board 3302 by coupling components 3328. The package-on-package structure 3334 may include a first IC package 3326 and a second IC package 3332 coupled together by coupling components 3330 such that the first IC package 3326 is disposed between the circuit board 3302 and the second IC package 3332. The coupling components 3328, 3330 may take the form of any of the examples of the coupling components 3316 discussed above, and the IC packages 3326, 3332 may take the form of any of the examples of the IC package 3320 discussed above. The package-on-package structure 3334 may be configured in accordance with any of the package-on-package structures known in the art.

FIG. 34 is a block diagram of an example electrical device 3400 that may include one or more of the example semiconductor dies 102, 104, 200, 500, 700, 900, 1300 disclosed herein. For example, any suitable ones of the components of the electrical device 3400 may include one or more of the device assemblies 3300, IC devices 3100, or dies 3002 disclosed herein. A number of components are illustrated in FIG. 34 as included in the electrical device 3400, but any one or more of these components may be omitted or duplicated, as suitable for the application. In some examples, some or all of the components included in the electrical device 3400 may be attached to one or more motherboards. In some examples, some or all of these components are fabricated onto a single system-on-a-chip (SoC) die.

Additionally, in various examples, the electrical device 3400 may not include one or more of the components illustrated in FIG. 34, but the electrical device 3400 may include interface circuitry for coupling to the one or more components. For example, the electrical device 3400 may not include a display 3406, but may include display interface circuitry (e.g., a connector and driver circuitry) to which a display 3406 may be coupled. In another set of examples, the electrical device 3400 may not include an audio input device 3418 (e.g., microphone) or an audio output device 3408 (e.g., a speaker, a headset, earbuds, etc.), but may include audio input or output device interface circuitry (e.g., connectors and supporting circuitry) to which an audio input device 3418 or audio output device 3408 may be coupled.

The electrical device 3400 may include programmable circuitry 3402 (e.g., one or more processing devices). The programmable circuitry 3402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 3400 may include a memory 3404, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 3404 may include memory that shares a die with the programmable circuitry 3402. This memory may be used as cache memory and may include embedded dynamic random access memory (eDRAM) or spin transfer torque magnetic random access memory (STT-MRAM).

In some examples, the electrical device 3400 may include a communication chip 3412 (e.g., one or more communication chips). For example, the communication chip 3412 may be configured for managing wireless communications for the transfer of data to and from the electrical device 3400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 3412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 3412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 3412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 3412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 3412 may operate in accordance with other wireless protocols in other examples. The electrical device 3400 may include an antenna 3422 to facilitate wireless communications and/or to receive other wireless communications (such as AM or FM radio transmissions).

In some examples, the communication chip 3412 may manage wired communications, such as electrical, optical, or any other suitable communication protocols (e.g., the Ethernet). As noted above, the communication chip 3412 may include multiple communication chips. For instance, a first communication chip 3412 may be dedicated to shorter-range wireless communications such as Wi-Fi or Bluetooth, and a second communication chip 3412 may be dedicated to longer-range wireless communications such as global positioning system (GPS), EDGE, GPRS, CDMA, WiMAX, LTE, EV-DO, or others. In some examples, a first communication chip 3412 may be dedicated to wireless communications, and a second communication chip 3412 may be dedicated to wired communications.

The electrical device 3400 may include battery/power circuitry 3414. The battery/power circuitry 3414 may include one or more energy storage devices (e.g., batteries or capacitors) and/or circuitry for coupling components of the electrical device 3400 to an energy source separate from the electrical device 3400 (e.g., AC line power).

The electrical device 3400 may include a display 3406 (or corresponding interface circuitry, as discussed above). The display 3406 may include any visual indicators, such as a heads-up display, a computer monitor, a projector, a touchscreen display, a liquid crystal display (LCD), a light-emitting diode display, or a flat panel display.

The electrical device 3400 may include an audio output device 3408 (or corresponding interface circuitry, as discussed above). The audio output device 3408 may include any device that generates an audible indicator, such as speakers, headsets, or earbuds.

The electrical device 3400 may include an audio input device 3418 (or corresponding interface circuitry, as discussed above). The audio input device 3418 may include any device that generates a signal representative of a sound, such as microphones, microphone arrays, or digital instruments (e.g., instruments having a musical instrument digital interface (MIDI) output).

The electrical device 3400 may include GPS circuitry 3416. The GPS circuitry 3416 may be in communication with a satellite-based system and may receive a location of the electrical device 3400, as known in the art.

The electrical device 3400 may include any other output device 3410 (or corresponding interface circuitry, as discussed above). Examples of the other output device 3410 may include an audio codec, a video codec, a printer, a wired or wireless transmitter for providing information to other devices, or an additional storage device.

The electrical device 3400 may include any other input device 3420 (or corresponding interface circuitry, as discussed above). Examples of the other input device 3420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 3400 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 3400 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve the reliability of multi-layer vias by providing lateral etch casings partially or completely surrounding the vias to prevent the etch chemistry used to create such vias from laterally spreading out and damaging exterior dielectric material, to prevent the corrosion of nearby metal features, and/or to prevent the formation of short circuits and/or open circuits. In some instances, when corrosion of the lateral etch casing is a concern (e.g., based on the severity of the etch chemistry), more than one lateral etch casing can be employed to provide redundance and/or increased reliability. Disclosed systems, apparatus, articles of manufacture, and methods are accordingly directed to one or more improvement(s) in the operation of a machine such as a computer or other electronic and/or mechanical device.

Further examples and combinations thereof include the following:

Example 1 includes an apparatus comprising a first dielectric layer, a second dielectric layer, a metal layer between the first and second dielectric layers, a multi-layer via that extends through the first and second dielectric layers and through the metal layer, and a ring in the metal layer, the ring substantially encircles the multi-layer via.

Example 2 includes any preceding clause(s) of example 1, including a conductive material electrically coupled to the ring, the conductive material extends through the first dielectric layer.

Example 3 includes any preceding clause(s) of any one or more of examples 1-2, wherein the ring is a metal layer ring, and the conductive material defines a via layer ring within the first dielectric layer.

Example 4 includes any preceding clause(s) of any one or more of examples 1-3, wherein the metal layer is a first metal layer, and the ring is a first ring, the apparatus including a second metal ring in a second metal layer, the multi-layer via extends through the second metal layer, the second ring substantially encircles the multi-layer via.

Example 5 includes any preceding clause(s) of any one or more of examples 1-4, wherein the first dielectric layer is between the first metal layer and the second metal layer, the apparatus including a conductive material that extends through the first dielectric layer from the first ring to the second ring.

Example 6 includes any preceding clause(s) of any one or more of examples 1-5, wherein the conductive material defines a third ring that substantially encircles the multi-layer via between the first and second rings.

Example 7 includes any preceding clause(s) of any one or more of examples 1-6, wherein the first and second rings define different portions of a first lateral etch casing, the apparatus including a second lateral etch casing around the multi-layer via, at least one of (a) an uppermost metal layer ring in the first lateral etch casing being in a different metal layer from an uppermost metal layer ring in the second lateral etch casing, or (b) a bottommost metal layer ring in the first lateral etch casing being in a different metal layer from a bottommost metal layer ring in the second lateral etch casing.

Example 8 includes any preceding clause(s) of any one or more of examples 1-7, wherein a first number of metal layer rings in the first lateral etch casing is different from a second number of metal layer rings in the second lateral etch casing.

Example 9 includes any preceding clause(s) of any one or more of examples 1-8, wherein the metal layer is a first metal layer, the apparatus including a first contact pad in a second metal layer, an end of the multi-layer via directly abuts the first contact pad, the first and second metal layers included in a first semiconductor chip, the first contact pad hybrid bonded to a second contact pad of a second semiconductor chip.

Example 10 includes any preceding clause(s) of any one or more of examples 1-9, wherein the multi-layer via is a first multi-layer via, the apparatus including a second multi-layer via that extends through the first and second dielectric layers and through the metal layer.

Example 11 includes any preceding clause(s) of any one or more of examples 1-10, wherein the ring substantially encircles both the first multi-layer via and the second multi-layer via.

Example 12 includes any preceding clause(s) of any one or more of examples 1-11, wherein the multi-layer via and the ring include a same metal.

Example 13 includes any preceding clause(s) of any one or more of examples 1-12, wherein the multi-layer via and the ring include different metals.

Example 14 includes any preceding clause(s) of any one or more of examples 1-13, wherein the ring is a first ring, the apparatus including a second metal ring in the metal layer, the second ring larger than the first ring.

Example 15 includes an apparatus comprising at least two conductive rings, the at least two conductive rings in different layers within a metallization region of a semiconductor die, and a conductive via extending through the at least two conductive rings.

Example 16 includes any preceding clause(s) of example 15, wherein two or more rings of the at least two conductive rings are located within a same metal layer within the metallization region, and a first one of the two or more rings surrounds a second one of the two or more rings.

Example 17 includes any preceding clause(s) of any one or more of examples 1-16, wherein different rings in the at least two conductive rings are aligned in a direction normal to the different layers.

Example 18 includes any preceding clause(s) of any one or more of examples 1-17, wherein the conductive via is a first conductive via, the apparatus including a second conductive via extending through the at least two conductive rings.

Example 19 includes an apparatus comprising a plurality of dielectric layers, a plurality of metal layers interleaved with the dielectric layers, a multi-layer via extending through at least two of the dielectric layers and an intervening one of the metal layers, and a lateral etch casing around the multi-layer via.

Example 20 includes any preceding clause(s) of example 19, wherein the lateral etch casing is a first lateral etch casing, the apparatus including a second lateral etch casing around the first lateral etch casing.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a first dielectric layer;
a second dielectric layer;
a metal layer between the first and second dielectric layers;
a multi-layer via that extends through the first and second dielectric layers and through the metal layer; and
a ring in the metal layer, the ring substantially encircles the multi-layer via.

2. The apparatus of claim 1, including a conductive material coupled to the ring, the conductive material extends through the first dielectric layer.

3. The apparatus of claim 2, wherein the ring is a metal layer ring, and the conductive material defines a via layer ring within the first dielectric layer.

4. The apparatus of claim 1, wherein the metal layer is a first metal layer, and the ring is a first ring, the apparatus including a second metal ring in a second metal layer, the multi-layer via extends through the second metal layer, the second ring substantially encircles the multi-layer via.

5. The apparatus of claim 4, wherein the first dielectric layer is between the first metal layer and the second metal layer, the apparatus including a conductive material that extends through the first dielectric layer from the first ring to the second ring.

6. The apparatus of claim 5, wherein the conductive material defines a third ring that substantially encircles the multi-layer via between the first and second rings.

7. The apparatus of claim 4, wherein the first and second rings define different portions of a first lateral etch casing, the apparatus including a second lateral etch casing around the multi-layer via, at least one of (a) an uppermost metal layer ring in the first lateral etch casing being in a different metal layer from an uppermost metal layer ring in the second lateral etch casing, or (b) a bottommost metal layer ring in the first lateral etch casing being in a different metal layer from a bottommost metal layer ring in the second lateral etch casing.

8. The apparatus of claim 7, wherein a first number of metal layer rings in the first lateral etch casing is different from a second number of metal layer rings in the second lateral etch casing.

9. The apparatus of claim 1, wherein the metal layer is a first metal layer, the apparatus including a first contact pad in a second metal layer, an end of the multi-layer via directly abuts the first contact pad, the first and second metal layers included in a first semiconductor chip, the first contact pad hybrid bonded to a second contact pad of a second semiconductor chip.

10. The apparatus of claim 1, wherein the multi-layer via is a first multi-layer via, the apparatus including a second multi-layer via that extends through the first and second dielectric layers and through the metal layer.

11. The apparatus of claim 10, wherein the ring substantially encircles both the first multi-layer via and the second multi-layer via.

12. The apparatus of claim 1, wherein the multi-layer via and the ring include a same metal.

13. The apparatus of claim 1, wherein the multi-layer via and the ring include different metals.

14. The apparatus of claim 1, wherein the ring is a first ring, the apparatus including a second metal ring in the metal layer, the second ring larger than the first ring.

15. An apparatus comprising:
at least two conductive rings, the at least two conductive rings in different layers within a metallization region of a semiconductor die; and
a conductive via extending through the at least two conductive rings.

16. The apparatus of claim 15, wherein two or more rings of the at least two conductive rings are located within a same metal layer within the metallization region, and a first one of the two or more rings surrounds a second one of the two or more rings.

17. The apparatus of claim 15, wherein different rings in the at least two conductive rings are aligned in a direction normal to the different layers.

18. The apparatus of claim 15, wherein the conductive via is a first conductive via, the apparatus including a second conductive via extending through the at least two conductive rings.

19. An apparatus comprising:
a plurality of dielectric layers;
a plurality of metal layers interleaved with the dielectric layers;
a multi-layer via extending through at least two of the dielectric layers and an intervening one of the metal layers; and
a lateral etch casing around the multi-layer via.

20. The apparatus of claim 19, wherein the lateral etch casing is a first lateral etch casing, the apparatus including a second lateral etch casing around the first lateral etch casing.
